(19) United States
(12) Patent Application Publication
(10) Pub. No.: US 2026/0068534 A1
(43) Pub. Date: Mar. 5, 2026

(54) MAGNETORESISTIVE DEVICE AND METHOD OF MANUFACTURING THE SAME, AND SEMICONDUCTOR DEVICE AND METHOD OF MANUFACTURING THE SAME

(71) Applicant: Samsung Electronics Co., Ltd., Suwon-si (KR)

(72) Inventors: Pham Nam HAI, Tokyo (JP); Shigeki TAKAHASHI, Yokohama (JP); Yoshiyuki HIRAYAMA, Yokohama (JP); Yushi KATO, Yokohama (JP)

(73) Assignee: Samsung Electronics Co., Ltd., Suwon-si (KR)

(21) Appl. No.: 19/316,529

(22) Filed: Sep. 2, 2025

(30) Foreign Application Priority Data
Sep. 3, 2024 (JP) 2024-151827
Apr. 29, 2025 (KR) 10-2025-0056757

(51) Int. Cl. H10N 50/01; G11C 11/16; H10N 50/10; H10N 50/85

(52) U.S. Cl. CPC H10N 50/01; H10N 50/10; H10N 50/85; G11C 11/161

(57) ABSTRACT

A method of manufacturing a magnetoresistive device includes: forming a spin-orbit torque (SOT) electrode layer that applies SOT to a first magnetic layer of a magnetic tunnel junction device by flowing current on a buffer layer, wherein the forming of the SOT electrode layer includes forming a sputtered film by sputtering a material containing BiSb on the buffer layer and forming a planarized sputtered film after planarizing the sputtered film by a surface planarization process, forming an intermediate layer on the SOT electrode layer, promoting crystallization of the SOT electrode layer by annealing the SOT electrode layer at a temperature greater than a melting point of BiSb and then cooling the SOT electrode layer, and forming a magnetic tunnel junction device on the intermediate layer, the magnetic tunnel junction device including a first magnetic layer, a non-magnetic layer, and a second magnetic layer formed on the non-magnetic layer.

### CROSS-REFERENCE TO RELATED APPLICATIONS

This application is based on and claims priority under 35 U.S.C. § 119 to Japanese Patent Application No. 2024-151827, filed on Sep. 3, 2024, in the Japan Patent Office, and Korean Patent Application No. 10-2025-0056757, filed on Apr. 29, 2025, in the Korean Intellectual Property Office, the disclosures of each of which are incorporated by reference herein in their entirety.

### BACKGROUND

The inventive concepts relate to magnetoresistive devices and methods of manufacturing the magnetoresistive devices, and semiconductor devices and methods of manufacturing the semiconductor devices.

Increasing the spin Hall angle, which is the conversion efficiency from current to spin current at an SOT electrode, may result in a reduction of the switching current of spin-orbit torque (SOT) magnetoresistive memory. Hereinafter, spin-orbit torque is also referred to as SOT, magnetoresistive random access memory is also referred to as MRAM, and spin-orbit torque magnetoresistive memory is also referred to as SOT-MRAM.

A technology using an SOT electrode in which bismuth antimony (hereinafter referred to as BiSb) of a topological insulator has a (012) crystal orientation have been explored for significantly increasing the spin Hall angle and reducing the switching current.

For example, a buffer layer for promoting (012) crystal orientation may provide a large spin Hall angle in a BiSb SOT electrode.

In addition, by using the BiSb SOT electrode with the crystal orientation oriented in the (012) plane direction, the spin Hall conductivity, which is an index of power saving, significantly increases, compared to a comparative case including W or Ta.

Therefore, manufacturing method for manufacturing magnetoresistive devices that would exhibit good characteristics thereof are being explored.

### SUMMARY

Thus, the inventive concepts provide a magnetoresistive device that may exhibit good characteristics.

According to an aspect of the inventive concepts, there is provided a magnetoresistive device, the magnetoresistive device including a buffer layer including at least one compound of oxide, nitride, and oxynitride, an SOT electrode layer on the buffer layer and configured to apply SOT to a first magnetic layer of an MTJ device by flowing current through the first magnetic layer, an intermediate layer on the SOT electrode layer, and the MTJ device on the intermediate layer, wherein the MTJ device may include a first magnetic layer, a non-magnetic layer provided on the first magnetic layer, and a second magnetic layer provided on the non-magnetic layer, the SOT electrode layer may include BiSb, a crystal structure of the SOT electrode layer may be such that a plane orientation of a crystal plane in a plane parallel to the first magnetic layer is preferentially oriented to BiSb(012), and a surface roughness of the SOT electrode layer, which is measured by micro-area analysis, may be about 0.5 nm or less as an arithmetic average roughness Ra, an electrical conductivity of the SOT electrode layer may be about 0.8×10⁵ Ω⁻¹ m⁻¹ or more, and a value of the spin Hall angle, which is the conversion efficiency from electric current to spin current, may be about 5 or more.

According to another aspect of the inventive concepts, there is provided a method of manufacturing a magnetoresistive device, the method including forming a buffer layer on an underlayer; forming a spin-orbit torque (SOT) electrode layer configured to apply SOT to a first magnetic layer of a magnetic tunnel junction device by flowing current on the buffer layer, the forming of the SOT electrode layer comprises forming a sputtered film by sputtering a material containing BiSb on the buffer layer, and forming a planarized sputtered film by planarizing the sputtered film using a surface planarization process; forming an intermediate layer on the SOT electrode layer; promoting crystallization of the SOT electrode layer by annealing the SOT electrode layer at a temperature greater than a melting point of BiSb and then cooling the SOT electrode layer; and forming the magnetic tunnel junction device on the intermediate layer, the magnetic tunnel junction device comprising the first magnetic layer, a non-magnetic layer formed on the first magnetic layer, and a second magnetic layer formed on the non-magnetic layer.

According to another aspect of the inventive concepts, there is provided a method of manufacturing a magnetoresistive device, the method including forming a buffer layer on an underlayer, forming a spin-orbit torque (SOT) electrode layer such that the SOT electrode layer is configured to apply SOT to a first magnetic layer of a magnetic tunnel junction device by flowing current on the buffer layer, the forming of the SOT electrode layer including forming an amorphous sputtered film by sputtering a material containing BiSb; forming an intermediate layer on the SOT electrode layer, promoting crystallization of the SOT electrode layer by annealing the SOT electrode layer at a temperature greater than a melting point of BiSb and then cooling the SOT electrode layer, and forming a magnetic tunnel junction device on the intermediate layer, the magnetic tunnel junction device including a first magnetic layer, a non-magnetic layer formed on the first magnetic layer, and a second magnetic layer formed on the non-magnetic layer.

According to another aspect of the inventive concepts, there is provided a magnetoresistive device, the magnetoresistive device including a magnetic tunnel junction (MTJ) device, an intermediate layer provided on a first magnetic layer of the MTJ device, an SOT electrode layer that may apply spin-orbit torque (SOT) to the first magnetic layer by flowing current therethrough, and a cap layer including at least one compound of oxide, nitride and oxynitride that are provided on the SOT electrode layer, wherein the MTJ device may include a second magnetic layer, a non-magnetic layer provided on the second magnetic layer, and the first magnetic layer provided on the non-magnetic layer, the SOT electrode layer may contain BiSb, and a crystal structure of the SOT electrode layer is such that the plane orientation of a crystal plane in a plane parallel to the first magnetic layer may be preferentially oriented to BiSb(012), the magnetoresistive device may include a pillar structure including the MTJ device and the intermediate layer, the SOT electrode layer may include a first portion α disposed on the intermediate layer in the pillar structure, and a second portion β disposed on a member that does not constitute the pillar structure, the first portion α and the second portion β may exist integrally, and the magnetoresistive device may satisfy at least one of the following (I) and the following (II):
(I) The first portion α may have a film thickness greater than that of the second portion β;
(II) The first portion α and the second portion β may exist continuously in terms of crystallography.

According to another aspect of the inventive concepts, there is provided a method of manufacturing a magnetoresistive device, the method including sequentially forming a magnetic tunnel junction device, an intermediate layer, and a first preliminary spin-orbit torque (SOT) electrode layer containing BiSb, on a base electrode, wherein the magnetic tunnel junction device may include a first magnetic layer, a non-magnetic layer formed on the first magnetic layer, and a second magnetic layer formed on the non-magnetic layer, etching the magnetic tunnel junction device, the intermediate layer, and the first preliminary SOT electrode layer to form a preliminary pillar structure, the preliminary pillar structure comprising the magnetic tunnel junction device, the intermediate layer, and the first preliminary SOT electrode layer, forming an interlayer insulating film on side and upper surfaces of the preliminary pillar structure, removing a portion of the interlayer insulating film to expose a portion of an upper portion of the first preliminary SOT electrode layer, forming a second preliminary SOT electrode layer containing BiSb on a surface of the exposed portion of the first preliminary SOT electrode layer and the interlayer insulating film such that a third preliminary SOT electrode layer is formed in which the first preliminary SOT electrode layer is connected to the second preliminary SOT electrode layer, forming a cap layer on the third preliminary SOT electrode layer, and forming a SOT electrode layer by crystallizing the third preliminary SOT electrode layer after forming the cap layer, the crystallizing the third preliminary SOT electrode layer including annealing the third preliminary SOT electrode layer at a temperature greater than a melting point of BiSb and then cooling the third preliminary SOT electrode layer.

### BRIEF DESCRIPTION OF THE DRAWINGS

Embodiments will be more clearly understood from the following detailed description taken in conjunction with the accompanying drawings in which:

FIG. 1 is a schematic diagram illustrating an example of a magnetoresistive device in the first to third embodiments;

FIG. 2A is a schematic diagram illustrating an example of a manufacturing method according to the second embodiment;

FIG. 2B is a schematic diagram illustrating an example of the manufacturing method according to the second embodiment;

FIG. 3 is a graph showing measurement results by a second harmonic Hall measurement method for a mock test device used in the description of Specific Example 1;

FIG. 4 is a graph showing measurement results by an X-ray diffraction method for a BiSb film in a stack used in the description of Specific Example 1;

FIG. 5A is a schematic diagram illustrating an example of a manufacturing method according to the third embodiment;

FIG. 5B is a schematic diagram illustrating an example of the manufacturing method according to the third embodiment;

FIG. 6 is a schematic diagram illustrating an example of a magnetoresistive device in the fourth to fifth embodiments;

FIG. 7 is a schematic diagram illustrating an example of a magnetoresistive device in the fourth to fifth embodiments;

FIG. 8A is a schematic diagram illustrating an example of a manufacturing method according to the fifth embodiment;

FIG. 8B is a schematic diagram illustrating an example of the manufacturing method according to the fifth embodiment;

FIG. 8C is a schematic diagram illustrating an example of the manufacturing method according to the fifth embodiment;

FIG. 8D is a schematic diagram illustrating an example of the manufacturing method according to the fifth embodiment;

FIG. 8E is a schematic diagram illustrating an example of the manufacturing method according to the fifth embodiment;

FIG. 8F is a schematic diagram illustrating an example of the manufacturing method according to the fifth embodiment;

FIG. 8G is a schematic diagram illustrating an example of the manufacturing method according to the fifth embodiment; and

FIG. 8H is a schematic diagram illustrating an example of the manufacturing method according to the fifth embodiment.

### DETAILED DESCRIPTION OF THE EMBODIMENTS

Hereinafter, embodiments of the inventive concepts will be described in detail, but the inventive concepts are not limited to the following embodiments and may be variously modified within the scope of the attaching claims. The embodiments described herein are examples, and may be combined and/or modified to form other example embodiments. Herein, the term “X to Y” indicating a range is used to mean “at least X but not more than Y”, including the numerical values (e.g., X and Y) as the lower and upper limits. Herein, “A and/or B” means each of A and B, and combinations thereof. When terms such as “approximately”, “substantially”, and/or the like are used in relation to numerical values, the relevant numerical value may be construed as including a manufacturing or operation deviation (e.g., ±10%) of the stated numerical value. Moreover, regardless of whether a numerical value of a shape is limited by using “approximately” or “substantially”, such numerical value or shape should be understood as including a manufacturing or operation deviation (e.g., ±10%) of the stated numerical value.

Hereinafter, embodiments will be described with reference to the attached drawings. In addition, in the description of the drawings, the same reference numerals are given to the same elements and duplicate descriptions will be omitted. In addition, the dimension ratios of the drawings are exaggerated for convenience of explanation, and may differ from the actual ratios.

Herein, when a first element, such as a layer, film, region, or plate, is “on” a second element, this includes not only the case where the first element is “directly on” the second element, but also the case where there is another part between them. “Above” and “over” are the same as “on” as including cases where there is another part therebetween. On the other hand, when the first element is “directly on” the second element, this means that there is no other part in between them. Furthermore, when the first element is “on the surface” of the second element, this means that there are no other parts in between them. Additionally, it will also be understood that spatially relative terms, such as “left”, “right”, “above”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly; and the term “upper portion” or “on” may also include “to be present above, below, in the left and right sides on a non-contact basis” as well as “to be on the top, bottom, left, and right portions in directly contact with”.

Herein, when a first element, such as a layer, film, region, or plate, is said to be “between” a second element and a third element, this includes cases where the first element is “directly above” or “directly below” the second element, and “directly below” or “directly above” the third element, as well as cases where there is another portion between the first element and the second element, between the second element and the third element, or on either side of these.

Herein, the term “oxide of at least one metal” may refer to an oxide of an elemental metal, a combination of oxides of multiple elemental metals, or a composite oxide of metals. For example, the oxide of at least one metal selected from magnesium (Mg) and aluminum (Al) may include an oxide of Mg, an oxide of Al, a combination of an oxide of Mg and an oxide of Al, or a composite oxide of Mg and Al.

Some embodiments of the inventive concepts relate to magnetoresistive devices, and other embodiments thereof relate to methods of manufacturing the magnetoresistive devices.

The magnetoresistive device of the example embodiments may include a buffer layer including at least one compound of oxide, nitride, and oxynitride, and/or a cap layer including at least one compound of oxide, nitride, and oxynitride, an spin-orbit torque (SOT) electrode layer that may apply SOT to a first magnetic layer of an a magnetic tunnel junction (MTJ) device by flowing current through the first magnetic layer of the MTJ device, an intermediate layer, and the MTJ device, wherein the SOT electrode layer may be between the buffer layer or the cap layer, and the MTJ device may include the first magnetic layer, a second magnetic layer, and a non-magnetic layer between the first magnetic layer and the second magnetic layer, and the SOT electrode layer may contain bismuth antimonide (BiSb).

In addition, in some embodiments, the buffer layer, the cap layer, and/or the intermediate layer may each independently contact the SOT electrode layer, or may not directly contact the SOT electrode layer. In addition, in some embodiments, the first magnetic layer and the second magnetic layer may independently and directly contact the non-magnetic layer, or may not directly contact the non-magnetic layer.

<Magnetoresistive Device with MTJ Device Placed on SOT Electrode Layer and Manufacturing Method Thereof>

### Embodiments 1 to 3

A first embodiment of the inventive concepts relates to a magnetoresistive device, the magnetoresistive device may include a buffer layer including at least one compound of oxide, nitride, and oxynitride, an SOT electrode layer provided on the buffer layer and applying SOT to a first magnetic layer of an MTJ device, an intermediate layer provided on the SOT electrode layer, and the MTJ device provided on the intermediate layer, wherein the MTJ device may include a first magnetic layer, a non-magnetic layer provided on the first magnetic layer, and a second magnetic layer provided on the non-magnetic layer, the SOT electrode layer may include BiSb, a crystal structure of the SOT electrode layer may be such that a plane orientation of a crystal plane in a plane parallel to the first magnetic layer may be preferentially oriented to BiSb(012), and a surface roughness of the SOT electrode layer, which is measured by micro-area analysis, may be about 0.5 nm or less as an arithmetic average roughness Ra, an electrical conductivity of the SOT electrode layer may be about 0.8×10⁵ Ω⁻¹ m⁻¹ or more, and a value of the spin Hall angle, which is the conversion efficiency from electric current to spin current, may be about 5 or more.

A second embodiment of the inventive concepts relates to a method of manufacturing the magnetoresistive device, wherein the magnetoresistive device may include a buffer layer including at least one compound of oxide, nitride, and oxynitride; an SOT electrode layer provided on the buffer layer and applying SOT to a first magnetic layer of an MTJ device, an intermediate layer provided on the SOT electrode layer, and the MTJ device provided on the intermediate layer, wherein the MTJ device may include a first magnetic layer, a non-magnetic layer provided on the first magnetic layer, and a second magnetic layer provided on the non-magnetic layer, the method may include forming the SOT electrode layer by a method including:
(1) forming a sputtered film by sputtering a material containing BiSb on the buffer layer;
(2) planarizing the sputtered film by a surface planarization process, and obtaining a planarized sputtered film;
(3) forming the intermediate layer on the planarized sputtered film; and
(4) after forming the intermediate layer, annealing the planarized sputtered film at a temperature of at least a melting point of BiSb, followed by cooling, thereby promoting crystallization of BiSb.

A third embodiment of the inventive concepts relates to a method of manufacturing a magnetoresistive device, wherein the magnetoresistive device may include a buffer layer including at least one compound of oxide, nitride, and oxynitride, an SOT electrode layer provided on the buffer layer and applying SOT to a first magnetic layer of an MTJ device, an intermediate layer provided on the SOT electrode layer, and the MTJ device provided on the intermediate layer, wherein the MTJ device may include a first magnetic layer, a non-magnetic layer provided on the first magnetic layer, and a second magnetic layer provided on the non-magnetic layer, the method may include forming the SOT electrode layer by:
(A) forming an amorphous sputtered film by sputtering a material containing BiSb on the buffer layer;
(B) forming the intermediate layer on the amorphous sputtered film; and
(C) after forming the intermediate layer, annealing the amorphous sputtered film at a temperature equal to or higher than a melting point of BiSb, followed by cooling, thereby promoting crystallization of BiSb.

Hereinafter, device structures for the first to third embodiments that may improve the flatness of the SOT electrode layer while exhibiting good SOT characteristics, will be described.

### (Device Configuration)

In at least one embodiment, a magnetoresistive device may further include an underlayer, or may not include the underlayer. The magnetoresistive device may preferably include the underlayer. In at least one embodiment, the magnetoresistive device may include the underlayer and a buffer layer may be provided on the underlayer. The buffer layer may be provided directly on the underlayer. An SOT electrode layer may preferably be provided directly on the buffer layer. An intermediate layer may be preferably provided directly on the SOT electrode layer. The SOT electrode layer may preferably be provided directly on the buffer layer, and the intermediate layer may be preferably provided directly on the SOT electrode layer. An MTJ device may preferably include a first magnetic layer, a non-magnetic layer provided directly on the first magnetic layer, and a second magnetic layer provided on the non-magnetic layer. The MTJ device may preferably be provided on the intermediate layer. The first magnetic layer may preferably be provided on the intermediate layer, and the first magnetic layer may preferably be provided directly on the intermediate layer. The MTJ device may preferably be provided directly on the intermediate layer, and the first magnetic layer may preferably be provided directly on the intermediate layer. On the other hand, a stack structure of the magnetoresistive device in the first to third embodiments is not limited thereto.

### (Underlayer)

The underlayer is a layer that may serve as a foundation for forming other layers.

In at least one embodiment, the underlayer may be an insulating buffer layer. The underlayer may include an insulator, such as silicon oxide (SiO₂). The underlayer may include a wiring metal, an underlayer electrode, etc. The underlayer may include silicon and/or sapphire, etc. The underlayer may include a single layer or a stack of two or more layers. For example, the underlayer may include a silicon substrate, a silicon substrate including an insulating film, or a sapphire substrate including an insulating film, etc. As a Specific Example, the underlayer may include a Si substrate including a SiO₂ film. There is no particular limitation on the thickness of the underlayer (the total thickness of the underlayer when the underlayer is a stack of two or more layers), but it is usually adopted to have a thickness that may sufficiently secure flatness thereof.

### (Buffer Layer)

The magnetoresistive device in the first to third embodiments may include a buffer layer including at least one compound of oxide, nitride, and oxynitride. In at least one embodiment, the buffer layer may have a crystal structure that may control a crystal orientation of an SOT electrode layer, which is formed by melting and subsequent crystallization of BiSb. For example, the crystal structure of the buffer layer may be selected such that the buffer layer serves as a nucleation promotor, and promotes an orientation during the crystal growth (e.g., BiSb(012)) of the SOT electrode layer. More specifically, a lattice parameter in the crystal structure of the buffer layer may create lattice strain in the BiSb, which promotes the formation of preferentially oriented crystal grains.

The ratio of an electrical conductivity (Ω⁻¹m⁻¹) of the buffer layer to an electrical conductivity (Ω⁻¹m⁻¹) of the SOT electrode layer (e.g., the electrical conductivity of the buffer layer/the electrical conductivity of the SOT electrode layer), may be, for example, less than about 1, and may be about 0.1 or less (the lower limit thereof is more than 0). In these ranges, the spin Hall angle may become larger. A method of measuring the electrical conductivity of the SOT electrode layer will be described below. A method of measuring the electrical conductivity of the buffer layer may be the same as the method of measuring the electrical conductivity of the SOT electrode layer, except that a measurement target is changed from the SOT electrode layer to the buffer layer.

Oxide, nitride and oxynitride in the buffer layer may be, respectively, a metal oxide, a metal nitride, and/or a metal oxynitride. Metals in the metal oxide, the metal nitride, and the metal oxynitride may include, for example, tantalum (Ta), titanium (Ti), magnesium (Mg), aluminum (Al), manganese (Mn), iron (Fe), and/or the like. When the buffer layer contains oxide, the oxide may be one type alone, or may be used in combination of two or more types. When the buffer layer contains nitride, the nitride may be one type alone, or may be used in combination of two or more types. When the buffer layer contains oxynitride, the oxynitride may be one type alone, or may be used in combination of two or more types. The buffer layer may include at least one compound of metal oxide, metal nitride and metal oxynitride, more preferably include oxide, still more preferably include metal oxide, and still more preferably include an oxide of at least one metal of Ta, Ti, Mg, Al, Mn and Fe. Here, the oxide may include a complex oxide.

The buffer layer may have a significant influence on the crystal structure of the SOT electrode layer after annealing and subsequent cooling (e.g., after melting and crystallization processes) as described in the Specific Examples described below. For example, when the crystal structure of the SOT electrode layer is preferentially oriented to BiSb(012) (e.g., when BiSb in the SOT electrode layer is preferentially oriented in the (012) plane orientation), a very large spin Hall angle may be obtained. Therefore, after the SOT electrode layer undergoes annealing treatment and subsequent cooling (e.g., after undergoing the melting and crystallization process), the buffer layer that is likely to have a crystal orientation of BiSb(012) may be applied. Examples of oxides included in such a buffer layer may include TaOₓ, TiOₓ, MgO, MgAl₂O₄, MnO, or FeO, etc. Herein, x in TaOₓ and x in TiOₓ each independently represent a number greater than 0. Thus, the buffer layer may preferably include at least one metal oxide of TaOₓ, TiOₓ, MgO, MgAl₂O₄, MnO, and FeO, and more preferably include at least one metal oxide of TaOₓ and TiOₓ.

The buffer layer may be preferably a sputtered film of at least one compound of oxide, nitride, and oxynitride.

When the buffer layer includes a metal element and at least one element of oxygen (O) and nitrogen (N), the total content of the metal element and the at least one element of oxygen and nitrogen in the buffer layer may be 50 atomic percent or more, 60 atomic percent or more, 80 atomic percent or more, 90 atomic percent or more, 95 atomic percent or more, 99 atomic percent or more, and 100 atomic percent (the upper limit is 100 atomic percent). The buffer layer may preferably include the metal element (preferably at least one element of Ta, Ti, Al, Mg, and Fe) and the at least one element of oxygen and nitrogen. The buffer layer may preferably include the metal element (preferably at least one element of Ta, Ti, Al, Mg, and Fe), the at least one element of oxygen and nitrogen, and an element of an inevitable impurity. The content of elements in the buffer layer may be evaluated, for example, by X-ray photoelectron spectroscopy (XPS). In addition, when analyzing a microscopic area from a cross-section of a stack structure, the content of elements in the buffer layer may be evaluated, for example, by transmission electron microscopy-energy dispersive X-ray spectroscopy (TEM-EDS).

The buffer layer may include a single layer or may include a stack structure of two or more layers. In at least one embodiment, the buffer layer may include a stack structure including two or more layers with different compositions. The number of layers may be, for example, two layers. For example, in the structure of “TiOₓ/TaOₓ” described in the Specific Example described below, e.g., the stacked structure of the TiOₓ film and the TaOₓ film, each layer may have a different role so that the characteristics of the magnetoresistive device may be further improved. In this case, the TiOₓ film at a lower side may have a function of suppressing the deterioration of electrical conductivity due to diffusion of oxygen from an interlayer insulating film such as SiO₂, which is part of the underlayer, to the SOT electrode layer. On the other hand, the TaOₓ film at an upper side may be suitable for promoting the crystal orientation of BiSb(012) in the SOT electrode layer. In addition, it is considered that when the TaOₓ film is formed through the TiOₓ layer rather than being formed as a single layer on the interlayer insulating film such as SiO₂, the function of promoting the crystal orientation of BiSb(012) of the SOT electrode layer by the TaOₓ film may be further enhanced. Thus, the buffer layer having the stack structure of two or more layers with different compositions, such as the “TiOₓ/TaOₓ” structure, e.g., the stack structure of TiOₓ film and TaOₓ film, may be less likely to deteriorate the electrical conductivity of the SOT electrode layer after annealing and subsequent cooling (e.g., after the melting and crystallization process), and the buffer layer may be more suitable for increasing the spin Hall angle because the buffer layer may promote the crystal orientation of BiSb(012) in the SOT electrode layer.

When the buffer layer has the stack structure including two or more layers with different compositions, each of the two or more layers with different compositions may equally apply the description with respect to the buffer layer.

When the buffer layer has the stack structure including two or more layers with different compositions the ratio of the electrical conductivity (Ω⁻¹m⁻¹) of each layer constituting the buffer layer to the electrical conductivity (Ω⁻¹m⁻¹) of the SOT electrode layer (e.g., the electrical conductivity of each layer constituting the buffer layer/the electrical conductivity of the SOT electrode layer) may be, for example, less than about 1, and may be preferably about 0.1 or less (the lower limit thereof is more than 0). In these ranges, the spin Hall angle may become larger. A method of measuring the electrical conductivity of the SOT electrode layer will be described below. The method of measuring the electrical conductivity of each layer constituting the buffer layer may be the same as the method of measuring the electrical conductivity of the SOT electrode layer, except that the measurement target is changed from the SOT electrode layer to each layer constituting the buffer layer.

When the buffer layer has the stack structure including two or more layers with different compositions, each of the two or more layers with different compositions may include at least one compound of oxide, nitride, and oxynitride. The two or more layers with different compositions may include at least one compound of metal oxide, metal nitride, and metal oxynitride. When any one or all layers of the two or more with different compositions include oxide, the oxide may be one type alone or two or more types used in combination. When any one or all layers of the two or more with different compositions include nitride, the nitride may be one type alone or two or more types used in combination. When any one or all layers of the two or more with different compositions include oxynitride, the oxynitride may be one type alone or two or more types used in combination. All of the two or more layers with different compositions may preferably include oxide, and they may more preferably include metal oxide. Each of the two or more layers with different compositions may preferably independently include an oxide of at least one metal of Ta, Ti, Mg, Al, Mn and Fe. Here, the oxide may include a complex oxide. Each of the two or more layers with different compositions may preferably independently include at least one metal oxide of TaOₓ, TiOₓ, MgO, MgAl₂O₄, MnO and FeO, and more preferably, they may include at least one metal oxide of TaOₓ and TiOₓ.

When the buffer layer has the stack structure including two or more layers with different compositions, each of the two or more layers with different compositions may independently include a sputtered film of at least one compound of oxide, nitride, and oxynitride. The buffer layer may more preferably include the sputtered film of TiOₓ or the sputtered film of TaOₓ.

When the buffer layer has the stack structure including the two or more layers with different compositions, and the two or more layers with different compositions may include a metal element and at least one element of oxygen and nitrogen, the total content of the metal element and the at least one element of oxygen and nitrogen in each of the two or more layers may be 50 atomic percent or more, 60 atomic percent or more, 80 atomic percent or more, 90 atomic percent or more, 95 atomic percent or more, 99 atomic percent or more, and 100 atomic percent (the upper limit is 100 atomic percent). All of the two or more layers with different compositions may preferably be composed of the metal element (preferably at least one element of Ta, Ti, Al, Mg and Fe) and at least one element of oxygen and nitrogen. All of the two or more layers with different compositions may be composed of the metal element (preferably at least one element of Ta, Ti, Al, Mg and Fe), at least one element of oxygen and nitrogen, and an element of an inevitable impurity. A method of evaluating the element content in each of the two or more layers may be the same as the method of evaluating the element content in the buffer layer.

In at least one embodiment, the film thickness of the buffer layer (e.g., the film thickness of each layer when the buffer layer is the stack structure of the two or more layers) may be at least about 0.1 nm but not more than about 25 nm, more preferably at least about 0.5 nm but not more than about 15 nm, and even more preferably at least about 1 nm but not more than about 10 nm.

### (SOT Electrode Layer)

The SOT electrode layer may be a layer that may apply SOT to the first magnetic layer in the MTJ device by flowing current therethrough.

The SOT electrode layer may contain BiSb. BiSb may be represented as Bi₁₋ₓSbₓ(0<x<1). The melting point of BiSb is affected by the composition thereof and on the ratio of x:1-x, but examples thereof may include a temperature of about 600° C. or less, a temperature of about 500° C. or less, a temperature of about 400° C. or less, and a temperature of about 300° C. or less. The SOT electrode layer may have a trigonal crystal structure. A stable structure of BiSb is a trigonal crystal, and a relatively large spin Hall angle may be obtained in a structure to which a (001) plane is preferentially oriented. In addition, the structure to which the (012) plane of BiSb is preferentially oriented may also exhibit a very large spin Hall angle. The crystal structure of the SOT electrode layer may have, for example, a plane orientation of a crystal plane in a plane parallel to the first magnetic layer is preferentially oriented to BiSb(012). Among these, it is particularly preferable that the SOT electrode layer may be a BiSb film having (012) orientation. The crystal structure of the SOT electrode layer may be evaluated by an X-ray diffraction method.

The SOT electrode layer may be the sputtered film of BiSb.

In at least one embodiment, the total content of BiSb in the SOT electrode layer may be 50 atomic percent or more, 60 atomic percent or more, 80 atomic percent or more, 90 atomic percent or more, 95 atomic percent or more, 99 atomic percent or more, and/or 100 atomic percent (the upper limit is 100 atomic percent). In at least one example, the SOT electrode layer may be composed only of Bi, Sb, and elements of inevitable impurities (e.g., in trace amounts). An example of the content of Sb in the SOT electrode layer may include at least about 7 atomic percent but not more than about 22 atomic percent. The content of elements in the SOT electrode layer may be evaluated by XPS, for example. In addition, when analyzing a microscopic area from a cross-section of a stack structure, the content of elements in the buffer layer may be evaluated by TEM-EDS, for example.

In view of the above, the smaller the surface roughness of the SOT surface roughness of the SOT electrode layer, measured by micro-area analysis the more preferable it is. Therefore, in at least one example, the surface roughness of the SOT electrode layer may be about 0.5 nm or less as an arithmetic mean roughness Ra (the lower limit is 0 nm).

The greater the electrical conductivity of the SOT electrode layer is, the more preferable it is. Therefore, the electrical conductivity of the SOT electrode layer may be about 0.8×10⁵ Ω⁻¹m⁻¹ or more, more preferably more than about 0.8×10⁵ Ω⁻¹m⁻¹, and still more preferably about 1×10⁵ Ω⁻¹m⁻¹ or more. The electrical conductivity of the SOT electrode layer may be, for example, at least about 0.8×10⁵ Ω⁻¹m⁻¹ but not more than about 6.0×10⁵ Ω⁻¹m⁻¹. The electrical conductivity of the SOT electrode layer may be measured using a four-terminal method of a Hall device, and the electrical conductivity of the SOT electrode layer in a stack may be measured using the four-terminal method of the Hall device, according to the method described in embodiments.

The film thickness of the SOT electrode layer may be, for example, at least about 1 nanometer (nm) but not more than 25 nm, more preferably at least about 2 nm but not more than 20 nm, and even more preferably at least about 5 nm but not more than about 15 nm.

### (Intermediate Layer)

The intermediate layer may have a function of passing spin current generated in the SOT electrode layer into a first magnetic layer, thereby applying SOT to the first magnetic layer. Preferably, the intermediate layer may have a crystal structure that may control the crystal orientation of the SOT electrode layer, which is formed by melting and subsequent crystallization of BiSb. For example, the crystal structure of the intermediate layer may be selected such that the intermediate layer serves as a nucleation promotor, and promotes an orientation during the crystal growth (e.g., BiSb(012)) of the SOT electrode layer. More specifically, a lattice parameter in the crystal structure of the intermediate layer may create lattice strain in the BiSb, which promotes the formation of preferentially oriented crystal grains.

The intermediate layer may include, for example, an elemental metal, an alloy of metals, a compound of a metal and a metalloid, a nitride (e.g., a metal nitride), an oxide (e.g., a metal oxide), an oxynitride (e.g., a metal oxynitride), and a boron-carbon-nitride (B—C—N) based material. These metals may include, for examples, metals having long spin diffusion lengths, such as titanium (Ti), aluminum (Al), silicon (Si), germanium (Ge), copper (Cu), molybdenum (Mo), vanadium (V), niobium (Nb), zinc (Zn), and tantalum (Ta).

For example, Ti, which is described in the Specific Example described below, may have a long spin diffusion length and may also be expected to improve spin transmittance, so that the spin current generated by the SOT electrode may be effectively injected into the first magnetic layer. In addition, oxides, nitrides, oxynitrides, etc., of the metals described above may also be suitable as the intermediate layer. Here, it is important that the intermediate layer has high spin transmittance. Therefore, more preferable examples of materials contained in the intermediate layer may include elemental metals made of the metal elements, alloys made by adding small amounts of other elements to these metal elements up to about 10 atomic percent, oxides of the metal elements, nitrides of the metal elements, and oxynitrides of the metal elements, etc. Specific Examples of materials in the intermediate layer may include elemental transition metals such as Ti and Ta, alloys of transition metals such as Ta—Cu, transition metal nitrides such as zirconium nitride (ZrN) and titanium nitride (TiN), or oxides of transition metal elements, etc. The intermediate layer may preferably be a material that promotes the crystal orientation of BiSb(012) of the SOT electrode layer during the annealing treatment and subsequent cooling (e.g., during the melting and crystallization process), but may be a material that does not inhibit the crystal orientation of BiSb(012). The material in the intermediate layer may be one type alone, or two or more types may be used in combination. The intermediate layer may preferably include at least one material of an elemental metal, an alloy of metals, a compound of a metal and a metalloid, a metal nitride, a metal oxide, a metal oxynitride, and a B—C—N based material, more preferably include at least one material of Ti, Al, Si, Ge, Cu, Mo, V, Nb, Zn, and Ta, oxides of these metals, nitrides of these metals, and oxynitrides of these metals, and still more preferably include at least one metal of Ta and Ti. The intermediate layer may include at least one of an elemental transition metal, an alloy of transition metals, a compound of a transition metal and a metalloid, a transition metal nitride, a transition metal oxide, a transition metal oxynitride, and a B—C—N based material.

The intermediate layer may preferably include a sputtered film including a metal element, and more preferably include a sputtered film of an elemental metal.

When the intermediate layer includes a metal element, the content of metal element in the buffer layer may be 50 atomic percent or more, 60 atomic percent or more, 80 atomic percent or more, 90 atomic percent or more, 95 atomic percent or more, 99 atomic percent or more, and 100 atomic percent (the upper limit is 100 atomic percent). The intermediate layer may preferably include a metal element (preferably, at least one element of Ti, Al, Si, Ge, Cu, Mo, V, Nb, Zn, and Ta). The intermediate layer may preferably be composed only of a metal element (preferably, at least one element of Ti, Al, Si, Ge, Cu, Mo, V, Nb, Zn, and Ta) and an element of an inevitable impurity. The content of elements in the intermediate layer may be evaluated by XPS, for example. In addition, when analyzing a microscopic area from a cross-section of a stack structure, the content of elements in the intermediate layer may be evaluated by TEM-EDS, for example.

The intermediate layer may include a single layer or may include a stack structure of two or more layers. The intermediate layer may preferably include a stack structure including two or more layers with different compositions. The number of layers may be, for example, two layers may be particularly preferable. The material in each layer may be one type alone, or two or more types may be used in combination. Each layer may preferably include at least one material of an elemental metal, an alloy of metals, a compound of a metal and a metalloid, a metal nitride, a metal oxide, a metal oxynitride, and a B—C—N based material, more preferably include at least one material of Ti, Al, Si, Ge, Cu, Mo, V, Nb, Zn, and Ta, oxides of these metals, nitrides of these metals, and oxynitrides of these metals, and still more preferably include at least one metal of Ta and Ti. When the intermediate layer has a stack structure consisting of two layers with different compositions, it is particularly preferable that one side contains an elemental Ta and the other side contains an elemental Ti. Each layer may independently include at least one of an elemental transition metal, an alloy of transition metals, a compound of a transition metal and a metalloid, a transition metal nitride, a transition metal oxide, a transition metal oxynitride, and a B—C—N based material.

When the intermediate layer has a stack structure including two or more layers with different compositions, it is preferable that the two or more layers with different compositions are each independently a sputtered film including a metal element, and it is more preferable that they are a sputtered film including an elemental metal. It is particularly preferable that the intermediate layer is a sputtered film of an elemental Ti and a sputtered film of an elemental Ta.

When the intermediate layer has a stack structure including the two or more layers with different compositions, and the two or more layers with different compositions include a metal element, the content of the metal element in each of the two or more layers may be, for example, 50 atomic percent or more, 60 atomic percent or more, 80 atomic percent or more, 90 atomic percent or more, 95 atomic percent or more, 99 atomic percent or more, and 100 atomic percent (the upper limit is 100 atomic percent). It is preferable that the two or more layers with different compositions are all composed of metal elements (preferably, at least one element of Ti, Al, Si, Ge, Cu, Mo, V, Nb, Zn, and Ta). It is preferable that the two or more layers with different compositions are only composed of metal elements (preferably, at least one element of Ti, Al, Si, Ge, Cu, Mo, V, Nb, Zn, and Ta) and an element of an inevitable impurity. The method of evaluating the element content in each of the two or more layers may be the same as the method of evaluating the element content in the intermediate layer.

It is preferable that the intermediate layer or a layer that may constitute the intermediate layer include a material having a long spin diffusion length. These materials may be, for example, an elemental Ti, an elemental Al, an elemental Si, an elemental Ge, an elemental Cu, an elemental Mo, an elemental V, an elemental Nb, an elemental Zn, or an elemental Ta. For example, the spin diffusion length of an elemental Ti may use a value of about 13 nm. For example, the spin diffusion length of an elemental Ta may use a value of about 5 nm. At least one layer of the buffer layer and the intermediate layer, or at least one layer of a cap layer described below and the intermediate layer may have a crystal structure that may control the crystal orientation of the SOT electrode layer formed by dissolution of BiSb and subsequent crystallization thereof. Additionally, the intermediate layer includes a material whose spin diffusion length is greater than a film thickness of the intermediate layer. When the intermediate layer is composed of two or more layers with different compositions, at least one layer constituting the intermediate layer may include a material having the spin diffusion length longer than the film thickness of the corresponding layer, and when the intermediate layer is composed of two or more layers with different compositions, all layers constituting the intermediate layer may include a material having the spin diffusion length longer than the film thickness of the respective corresponding layer. The ratio of the spin length of the constituent material of the intermediate layer or the layer that may constitute the intermediate layer to the film thickness of the intermediate layer or the layer that may constitute the intermediate layer may be, for example, at least about 0.10 but less than about 1.00, preferably at least about 0.15 but not more than about 0.60, more preferably at least about 0.20 not more than about 0.40.

A film thickness of the intermediate layer (the film thickness of each layer when the intermediate layer is the stack structure of the two or more layers) may be at least about 0.1 nm but not more than about 20 nm, more preferably at least about 0.5 nm but not more than about 10 nm, and even more preferably at least about 1 nm but not more than about 5 nm.

### (MTJ Device)

The MTJ device may include a first magnetic layer, a non-magnetic layer, and a second magnetic layer.

### <First Magnetic Layer (Recording Layer)>

The first magnetic layer may include a magnetic material. The first magnetic layer may include a ferromagnetic material. The first magnetic layer may function as a recording layer of the MTJ device. Therefore, the SOT may be applied to the first magnetic layer of the MTJ device by the current flowing through the SOT electrode layer.

The first magnetic layer may include at least one element of cobalt (Co), iron (Fe), nickel (Ni), manganese (Mn), boron (B), silicon (Si), zirconium (Zr), niobium (Nb), tantalum (Ta), ruthenium (Ru), iridium (Ir), platinum (Pt), gallium (Ga), aluminum (Al), palladium (Pd), terbium (Tb), gadolinium (Gd), and/or the like. In at least one embodiment, the first magnetic layer may include CoFeB.

The first magnetic layer may be the sputtered film of at least one element of Co, Fe, Ni, Mn, B, Si, Zr, Nb, Ta, Ru, Ir, Pt, Ga, Al, Pd, Tb, and Gd. In at least one embodiment, the first magnetic layer may be the sputtered film of CoFeB.

When the first magnetic layer includes at least one element of Co, Fe, Ni, Mn, B, Si, Zr, Nb, Ta, Ru, Ir, Pt, Ga, Al, Pd, Tb, and Gd, the total content of these elements in the first magnetic layer may be 50 atomic percent or more, 60 atomic percent or more, 80 atomic percent or more, 90 atomic percent or more, 95 atomic percent or more, 99 atomic percent or more, 100 atomic percent, and the like (the upper limit is 100 atomic percent). Examples of the total content of at least one element of Co, Fe, and B in the first magnetic layer may include 50 atomic percent or more, 60 atomic percent or more, 80 atomic percent or more, 90 atomic percent or more, 95 atomic percent or more, 99 atomic percent or more, 100 atomic percent, etc. (the upper limit is 100 atomic percent). In at least one embodiment, the first magnetic layer may be composed of at least one element of Co, Fe, Ni, Mn, B, Si, Zr, Nb, Ta, Ru, Ir, Pt, Ga, Al, Pd, Tb, and Gd. In at least one embodiment, the first magnetic layer may be composed only of at least one element of Co, Fe, Ni, Mn, B, Si, Zr, Nb, Ta, Ru, Ir, Pt, Ga, Al, Pd, Tb, and Gd and elements of inevitable impurities.

The film thickness of the first magnetic layer may be, for example, at least about 0.1 nm but not more than 25 nm, more preferably at least about 0.1 nm but not more than 10 nm, and still more preferably at least about 0.5 nm but not more than 5 nm.

### <Non-Magnetic Layer>

The non-magnetic layer may include a non-magnetic material. The non-magnetic layer may function as a tunnel barrier layer of the MTJ device. The non-magnetic layer may include at least one metal element of gallium (Ga), aluminum (Al), magnesium (Mg), hafnium (Hf), zirconium (Zr), and/or the like. The non-magnetic layer may include an oxide of at least one metal of Ga, Al, Mg, Hf and Zr. Here, the oxide may include a complex oxide. In at least one embodiment, the non-magnetic layer may include magnesium oxide (MgO).

It is preferable that the non-magnetic layer may be the sputtered film of MgO.

When the non-magnetic layer contains at least one element of Ga, Al, Mg, Hf, Zr, and oxygen (O), the total content of these elements may be 50 atomic percent or more, 60 atomic percent or more, 80 atomic percent or more, 90 atomic percent or more, 95 atomic percent or more, 99 atomic percent or more, 100 atomic percent, etc. (the upper limit 100 is atomic percent). Examples of the total content of at least one element of Mg and O in the non-magnetic layer may include 50 atomic percent or more, 60 atomic percent or more, 80 atomic percent or more, 90 atomic percent or more, 95 atomic percent or more, 99 atomic percent or more, and 100 atomic percent (the upper limit is 100 atomic percent). In at least one embodiment, the non-magnetic layer may be composed of at least one element of Ga, Al, Mg, Hf, Zr, and O. In at least one embodiment, the non-magnetic layer may be composed only of at least one element of Ga, Al, Mg, Hf, Zr and O and an element of an inevitable impurity.

The film thickness of the non-magnetic layer may be, for example, at least about 0.1 nm but not more than 25 nm, more preferably at least about 0.1 nm but not more than 10 nm, and still more preferably at least about 0.5 nm but not more than 5 nm.

### <Second Magnetic Layer>

The second magnetic layer may include a magnetic material. The second magnetic layer may include a ferromagnetic material. In at least one embodiment, the second magnetic layer may function as a recording layer of the MTJ element.

In at least one embodiment, the second magnetic layer may include at least one element of Co, Fe, Ni, Mn, B, Si, Zr, Nb, Ta, Ru, Ir, Pt, Ga, Al, Pd, Tb, and Gd. In at least one embodiment, the second magnetic layer may include CoFeB.

In at least one embodiment, the second magnetic layer may be the sputtered film of at least one element of Co, Fe, Ni, Mn, B, Si, Zr, Nb, Ta, Ru, Ir, Pt, Ga, Al, Pd, Tb, and Gd, and in at least one embodiment, the first magnetic layer may be the sputtered film of CoFeB.

When the second magnetic layer includes at least one element of Co, Fe, Ni, Mn, B, Si, Zr, Nb, Ta, Ru, Ir, Pt, Ga, Al, Pd, Tb, and Gd, the total content may be 50 atomic percent or more, 60 atomic percent or more, 80 atomic percent or more, 90 atomic percent or more, 95 atomic percent or more, 99 atomic percent or more, 100 atomic percent, and the like (the upper limit is 100 atomic percent). Examples of the total content of at least one element of Co, Fe, Ni, Mn, B, Si, Zr, Nb, Ta, Ru, Ir, Pt, Ga, Al, Pd, Tb, and Gd in the second magnetic layer may include 50 atomic percent or more, 60 atomic percent or more, 80 atomic percent or more, 90 atomic percent or more, 95 atomic percent or more, 99 atomic percent or more, 100 atomic percent, and the like (the upper limit is 100 atomic percent). In at least one embodiment, the second magnetic layer may be composed of at least one element of Co, Fe, Ni, Mn, B, Si, Zr, Nb, Ta, Ru, Ir, Pt, Ga, Al, Pd, Tb, and Gd. In at least one embodiment, the second magnetic layer may be composed only of at least one element of Co, Fe, Ni, Mn, B, Si, Zr, Nb, Ta, Ru, Ir, Pt, Ga, Al, Pd, Tb, and Gd and elements of inevitable impurities.

The film thickness of the second magnetic layer may be, for example, at least about 0.1 nm but not more than 25 nm, more preferably at least about 0.1 nm but not more than 10 nm, and still more preferably at least about 0.5 nm but not more than 5 nm.

The content of elements in the first magnetic layer, the content of elements in the non-magnetic layer, and the content of elements in the second magnetic layer may each be evaluated by XPS, for example. In addition, when analyzing a microscopic area from a cross-section of a stack structure, the content of elements in the first magnetic layer, the content of elements in the non-magnetic layer, and the content of elements in the second magnetic layer may each be evaluated by TEM-EDS, for example.

(Layers Other than Those Described Above)

The magnetoresistive device in the first to third embodiments may further include layers and/or other members other than those described above.

### (Device Characteristics)

In the magnetoresistive device of the first to third embodiments, the value of the spin Hall angle, which is the conversion efficiency from current to spin current, may be preferably at least about 5, more preferably greater than 5, and even more preferably more than 10. The value of the spin Hall angle may be measured by a second harmonic Hall measurement method. In at least one embodiment, the crystal structure of the SOT electrode layer is such that the plane orientation of a crystal plane in a plane parallel to the first magnetic layer is preferentially oriented to BiSb(012), the surface roughness measured by micro-area analysis of the SOT electrode layer may be about 0.5 nm or less as an arithmetic mean roughness Ra, the electrical conductivity of the SOT electrode layer may be about 0.8×10⁵ Ω⁻¹m⁻¹ or more (more preferably more than about 0.8×10⁵ Ω⁻¹m⁻¹, even more preferably about 1×10⁵ Ω⁻¹m⁻¹ or more), and the value of the spin Hall angle, which is a conversion efficiency from current to spin current in a magnetoresistive device, may be about 5 or more (more preferably more than about 5, even more preferably about 10 or more). The crystal structure of the SOT electrode layer and the method of measuring the electrical conductivity of the SOT electrode layer are the same as those described for the SOT electrode layer.

### (Method of Manufacturing a Magnetoresistive Device)

A manufacturing method of the magnetoresistive device in the first embodiment may include a manufacturing method according to the second embodiment or a manufacturing method according to the third embodiment. In at least one embodiment, the magnetoresistive device manufactured in the second embodiment and the third embodiment may be the magnetoresistive device according to the first embodiment, and therefore repeat descriptions thereof may be omitted for brevity. However, the magnetoresistive device manufactured in the second embodiment and the third embodiment is not limited thereto.

In the second embodiment and the third embodiment, a film formation method of each layer other than the SOT electrode layer of the magnetoresistive device may include, for example, a molecular beam epitaxy method, a sputtering method, a plasma method, a vacuum deposition method, and combinations thereof. In the first to third embodiments, it is preferable that the SOT electrode layer may be formed by the sputtering method. As for the sputtering method may include, for example, a magnetron sputtering method.

In the second embodiment, the temperature during a sputtering film formation of a material including BiSb may be, for example, at least at room temperature. Herein, performing the sputtering film formation at room temperature may mean performing the sputtering film formation in a state where temperature control is not specifically performed. In at least one embodiment, the sputtering film formation of the material including BiSb may be performed at a temperature of about 20° C. or more. In at least one embodiment, the sputtering film formation of the material including BiSb may be performed at a temperature of at least about 20° C. but not more than about 250° C., and/or at a temperature of at least about 20° C. but not more than about 100° C. When performing the sputtering film formation of the material including BiSb within these temperature ranges, the surface roughness value of the sputtered film may generally tend to be large, so the effect of the inventive concepts may be more effectively exhibited. A method of performing the sputtering film formation at a temperature exceeding room temperature may include, for example, a method of performing the sputtering film formation while heating an object on which the sputtered film is to be formed, to a temperature exceeding room temperature, preferably a temperature within the ranges above. In at least one embodiment, the sputtering film formation of the material including BiSb may be performed at a temperature of less than about 20° C., at a temperature of about 10° C. or less, or at a temperature of less than about 10° C.

In the third embodiment, the temperature during a sputtering film formation of a material including BiSb may be, for example, performed at a temperature less than room temperature. In at least one embodiment, the sputtering film formation of the material including BiSb may be preferably performed at a temperature of less than about 20° C., more preferably at a temperature of about 10° C. or less, and even more preferably at a temperature of less than about 10° C. In at least one embodiment, the sputtering film formation of the material including BiSb may be performed at a temperature of, for example, at least about −173° C. but less than about 20° C., at least about −173° C. but not more than about 10° C., at least about −173° C. but less than about 10° C. or not more than about 0° C., or at least about −173° C. but not more than about 0° C. By performing the sputtering film formation of the material including BiSb at these temperatures, the surface roughness values thereof may further decrease. In addition, by performing the sputtering film formation of the material including BiSb at these temperatures, an amorphous-type sputtered film may be easily formed. The method of performing the sputtering film formation at a temperature below room temperature may include a method of performing the sputtering film formation in a cooled state on the object on which the sputtered film is to be formed, preferably in a cooled state on which the object on which the sputtered film is to be formed, is cooled to the temperature within each of the ranges above.

In the second embodiment, a method of planarizing a surface of the sputtered film (the sputtered film including BiSb) by a surface planarization process may include, for example, an ion milling method, etc. In the surface planarization process, the surface roughness measured by the micro-area analysis may be about 0.5 nm or less (the lower limit exceeds 0 nm). In the surface planarization process, the sputtered film in which surface roughness measured by the micro-area analysis exceeds about 0.5 nm as the arithmetic mean roughness Ra may be planarized to about 0.5 nm or less as the arithmetic mean roughness Ra (the lower limit exceeds 0 nm). In the surface planarization process, the sputtered film in which surface roughness measured by the micro-area analysis is about 0.5 nm or less as the arithmetic mean roughness Ra may maintain to about 0.5 nm or less as the arithmetic mean roughness Ra, or may further decrease (the lower limit exceeds 0 nm). After the surface planarization process, the surface roughness of the sputtered film may be about 0.5 nm or less as the arithmetic mean roughness Ra (the lower limit is 0 nm). The surface roughness of the sputtered film may be measured by the micro-area analysis. The micro-area analysis may be performed, for example, using an atomic force microscope. It is preferable that the micro-area analysis may be performed on an area of, for example, about 1 μm×about 1 μm.

In the third embodiment, the surface roughness of the amorphous sputtered film (the amorphous sputtered film including BiSb) may be a smaller value, and/or may be about 0.5 nm or less as the arithmetic mean roughness Ra (the lower limit is 0 nm). The surface roughness of the sputtered film may be measured by the micro-area analysis. The micro-area analysis may be performed, for example, using an atomic force microscope. It is preferable that the micro-area analysis may be performed on an area of, for example, about 1 μm×about 1 μm.

In the third embodiment, the formation of the amorphous sputtered film (the amorphous sputtered film including BiSb) may be confirmed by, for example, an X-ray diffraction method.

A manufacturing method according to the second embodiment may include performing annealing treatment (e.g., SOT electrode annealing treatment) on the sputtered film (the sputtered film including BiSb). A manufacturing method according to the third embodiment may include performing annealing treatment (e.g., SOT electrode annealing treatment) on the sputtered film (the amorphous sputtered film including BiSb). In the second embodiment and the third embodiment, a method of the annealing treatment (e.g., the SOT electrode annealing treatment) and a condition of the annealing treatment (e.g., the SOT electrode annealing treatment) may include, for example, a method of performing annealing in a vacuum in the annealing chamber up to a predefined temperature, using a composite process apparatus in which a deposition chamber and an annealing chamber are connected by a high vacuum transport path. In the second embodiment and the third embodiment, the temperature of the annealing treatment may be a temperature higher than the melting point of BiSb, but may be preferably at least about 300° C. but not more than about 600° C., and more preferably at least about 400° C. but not more than about 500° C. When the temperature of the annealing treatment is within these ranges, the crystallization of the SOT electrode layer may be promoted well while deterioration of circuit portions of the magnetoresistive device may be well suppressed. The temperature of the annealing treatment may indicate a surface temperature (e.g., a film surface temperature) of an annealing treatment target. In the second embodiment and the third embodiment, the time of the annealing treatment may be at least about 5 minutes but not more than about 120 minutes, more preferably at least about 5 minutes but not more than 60 minutes, and still more preferably at least about 5 minutes but not more than about 30 minutes. When the time of the annealing treatment is within these ranges, the magnetoresistive device may be efficiently manufactured while ensuring good crystallization of the SOT electrode layer.

In the second embodiment and the third embodiment, methods and conditions of cooling may be, for example, natural cooling from the temperature during the annealing treatment, or may be cooling by lowering the ambient temperature to a low temperature (e.g., room temperature) after the annealing treatment, and/or include a sample substrate holder be cooled by controlling the temperature thereof to a low temperature. The cooling method may be preferable a method that includes leaving the sputtered film after the annealing treatment (e.g., the annealing treatment of the SOT electrode). A pressure during the leaving of the sputtered film may be, for example, about 10⁻⁵ Pa or less or about 10⁻⁶ Pa or less (the lower limit thereof is 0 Pa). The time of leaving thereof may be, for example, at least about 10 minutes but not more than about 10 hours, or at least about 30 minutes but not more than about 2 hours, etc.

In at least one embodiment, the method of manufacturing the magnetoresistive device may preferably further include performing a post-annealing treatment on some or all of main portions of the magnetoresistive device after the annealing treatment (e.g., after the annealing treatment of the SOT electrode) and cooling. Methods and conditions for the post-annealing treatment may be, for example, performed at least about 250° C. not more than 400° C., and more preferably at least about 250° C. but not more than 350° C. When the temperature of the post-annealing treatment is within these ranges, the performance of the magnetoresistive device may be further improved. The temperature of the post-annealing treatment may indicate a surface temperature (e.g., a film surface temperature) of a post-annealing treatment target. The time of the post-annealing treatment but may be at least about 5 minutes but not more than 60 minutes, and more preferably at least about 5 minutes but not more than about 30 minutes. When the time of the post-annealing treatment is within these ranges, the magnetoresistive device may be manufactured efficiently while maintaining good performance of the magnetoresistive device.

In the second embodiment, as in (4) described above, after forming the intermediate layer, the planarized sputtered film may be annealed at the temperature of at least the melting point of BiSb and then cooled to promote crystallization of BiSb, whereby the SOT electrode layer may be obtained from the planarized sputtered film.

In the third embodiment, as in (C) described above, after forming the intermediate layer, the amorphous sputtered film may be annealed at the temperature of at least the melting point of BiSb and then cooled to promote crystallization of BiSb, whereby the SOT electrode layer may be obtained from the amorphous sputtered film.

In at least one embodiment, the method of manufacturing the magnetoresistive device may further include operations and/or processes other than those described above.

According to manufacturing methods according to the second and third embodiments, the magnetoresistive device in which the MTJ device is disposed on top of the SOT electrode layer may be manufactured without deteriorating the good SOT switching characteristics inherent in the SOT electrode layer including BiSb, so that a significant improvement in the characteristics of the magnetoresistive device may be expected.

According to the examples of the first to third embodiments, a high-performance SOT-MRAM device may be realized by increasing the write efficiency of the SOT device and improving the read efficiency of the MTJ device at the same time.

### Specific Example 1

Hereinafter, the first and second embodiments will be described in more detail with Specific Examples. However, the first and second embodiments are not limited to the Specific Examples below.

### <1. Configuration of Magnetoresistive Device>

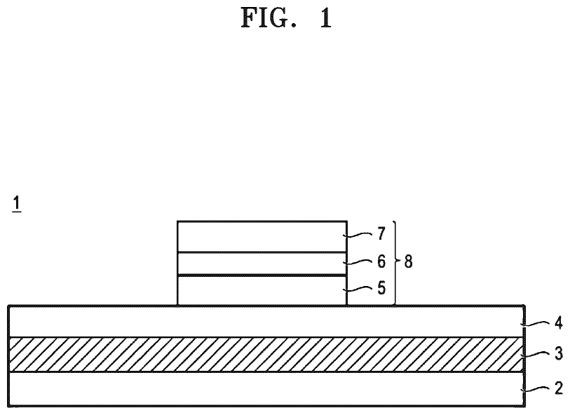

The configuration of main portion 1 of a magnetoresistive device (e.g., an SOT-MRAM device) described in Specific Example 1 is illustrated in FIG. 1. The magnetoresistive device illustrated in FIG. 1 may be formed by forming a stack structure using a sputtering film formation device, in which the stack structure include, in order from bottom to top, an interlayer insulating film (not shown) such as SiO₂, an oxide buffer layer (for example, a buffer layer 2), a BiSb film (for example, a SOT electrode layer 3), an intermediate layer 4, a ferromagnetic recording layer (for example, a first magnetic layer 5), a tunnel barrier layer (for example, a non-magnetic layer 6), and a ferromagnetic reference layer (for example, a second magnetic layer 7), and then forming an MTJ device 8 formed by patterning the ferromagnetic recording layer (for example, the first magnetic layer 5), the tunnel barrier layer (for example, the non-magnetic layer 6), and the ferromagnetic reference layer (for example, the second magnetic layer 7). In addition, sputtering film formation may be performed at room temperature.

That is, the magnetoresistive device illustrated in FIG. 1 may have a stack structure that includes, in this order from bottom, the oxide buffer layer (e.g., the buffer layer 2), the BiSb film (e.g., the SOT electrode layer 3), the intermediate layer 4, the ferromagnetic recording layer (e.g., the first magnetic layer 5), the tunnel barrier layer (e.g., the non-magnetic layer 6), and the ferromagnetic reference layer (e.g., the second magnetic layer 7) on the interlayer insulating film (not shown) such as SiO₂.

### <2. Relationship Between SOT Electrode Layer, Surface Roughness, and Spin Hole Angle>

In comparative examples, when the BiSb film is formed by sputtering, the surface roughness of the BiSb film is large, such as about 6 Å, due to the grain growth of the BiSb film. Further, while a SOT top structure in which the BiSb film is deposited on a ferromagnetic layer having a smooth surface can be formed, it is difficult to achieve a large spin Hall angle in a device with a BiSb bottom structure in which the ferromagnetic layer is deposited on the BiSb film, and that the reason for this is due to the surface roughness of the BiSb film. For this, when a BiSb film with a thickness of 10 nm, a Co film with a thickness of 1 nm, and a Pt film with a thickness of 1 nm are sequentially deposited by sputtering on a sapphire substrate in that order from the bottom, the arithmetic average roughness Ra of a surface of the Pt film measured using an atomic force microscope increases to about 0.7 nm. This is thought to be because the arithmetic average roughness Ra of the surface of the Pt film is derived from the arithmetic average roughness of the surface of the BiSb film existing below the Pt film and the Co film, which are ferromagnetic layers, and the BiSb film also has the same level of surface roughness. Here, the Co film and the Pt film may constitute a ferromagnetic layer. In addition, in a structure in which the BiSb film with a thickness of 10 nm, the Co film with a thickness of 1 nm, and the Pt film with a thickness of 1 nm are sequentially formed on the sapphire substrate, in this order from the bottom, by sputtering film formation, it is known that the spin Hall angle obtained is a small value of 0.9. The reason for this is thought to be that the large arithmetic average roughness of the surface of the BiSb film may cause a large spin diffusion loss at an interface between the BiSb film as the SOT electrode layer and the ferromagnetic layer.

The surface roughness of the BiSb film was measured using an atomic force microscope for a stack obtained by directly sputtering the BiSb film of a thickness of about 10 nm on a sapphire substrate at room temperature, and performed a micro-area analysis for an area of 1 μm×1 μm. As a result, the surface roughness of the BiSb film measured by the micro-area analysis was confirmed to be about 0.7 nm as the arithmetic average roughness Ra. This result is considered to support the above consideration.

On the other hand, in SOT top structure (e.g., a BiSb top structure) in which a BiSb film is deposited on a ferromagnetic layer with a smooth surface, a high spin Hall angle of 12.3 may be obtained in a structure in which a Co film with a thickness of 1 nm, a Pt film with a thickness of 1 nm, a Co film with a thickness of 1 nm, a Pt film with a thickness of 1 nm, and a BiSb film with a thickness of 10 nm are formed in this order from the bottom by sputtering film formation. Here, a multilayer film of the Co film and the Pt film may constitute a ferromagnetic layer. The reason why this sample exhibited a high spin Hall angle may be considered to be that the ferromagnetic layer may have a smooth surface, so the surface of the BiSb film present on top of the multilayer film of the Co film and the Pt film constituting the ferromagnetic layer may be as smooth as the ferromagnetic layer. In this case, it is considered that the arithmetic average roughness of the surface of the BiSb film may be small, so the occurrence of the spin diffusion loss at the interface between the BiSb film as the SOT electrode layer and the ferromagnetic layer may decrease.

The surface roughness of the Co film was measured using an atomic force microscope for a stack obtained by directly sputtering the Pt film of a thickness of 1 nm, the Co film of a thickness of 1 nm, and the Pt film of a thickness of 1 nm on a sapphire substrate in this order from the bottom, and performed a micro-area analysis for an area of 1 μm×1 μm. As a result, the surface roughness of the Co film measured by the micro-area analysis was confirmed to be about 0.1 nm as the arithmetic average roughness Ra. This result is considered to support the above consideration.

Thus, in the SOT-MRAM device having the SOT electrode layer including BiSb, it may be understood that it is important to improve the flatness of the interface between the SOT electrode layer including BiSb (in this Specific Example, the BiSb film) and the ferromagnetic layer in order to obtain high spin Hall angle characteristics.

### <3. Relationship Between Surface Planarization Treatment of SOT Electrode Layer and Crystallinity of SOT Electrode Layer>

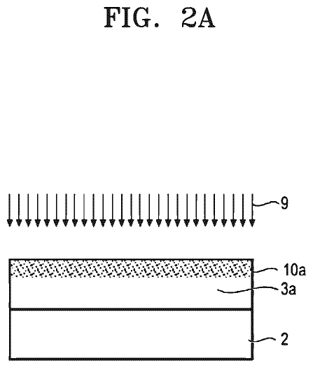

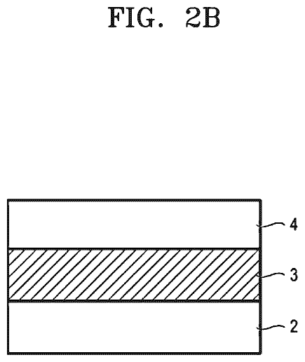

As a method of improving the flatness of a film surface, a method of performing a surface planarization treatment, such as ion milling, on the film surface is shown. First, as illustrated in FIG. 2A, an oxide buffer layer (e.g., the buffer layer 2) and a BiSb film (e.g., the sputtered BiSb film 3a) may be successively formed in this order from the bottom by sputtering, on an underlayer (not shown) including an interlayer insulating film and/or a wiring metal. As described above, when the BiSb film having a film thickness of 10 nm is formed by the sputtering film formation at room temperature, the surface roughness measured by the micro-area analysis of the BiSb film may be generally considered to be a large value, such as about 0.6 nm to about 0.7 nm as the arithmetic average roughness Ra. Next, a surface planarization treatment 9 such as ion milling may be performed on the surface of the BiSb film by a vacuum integrated process. When the surface planarization treatment 9 such as ion milling is performed, convex portions of the surface thereof may be selectively etched, so the surface roughness measured by the micro-area analysis of the BiSb film may be made smaller, and the surface roughness measured by the micro-area analysis of the BiSb film having a film thickness of 10 nm, which may be formed by sputtering at room temperature may be improved to 0.5 nm or less as the arithmetic average roughness Ra. The micro-area analysis may be performed using an atomic force microscope. It is preferable that the micro-area analysis may be performed on an area of about 1 μm×about 1 μm.

However, when the surface planarization treatment 9 such as ion milling is performed on the surface of the BiSb film (e.g., the sputtered BiSb film 3a), etching damage may occur on the surface of the BiSb film (e.g., the sputtered BiSb film 3a) after the surface planarization treatment 9, resulting in deterioration of crystallinity. A portion where etching damage exists in the SOT electrode layer 3 may be indicated as an etching damage portion 10a in FIG. 2A.

The reason why the high spin Hall angle may be obtained using the BiSb film is because the BiSB acts as a topological insulator (due to which the crystal structure and electronic structure of the BiSb film), and due to the surface current which are specific to topological insulators. When the crystallinity of the surface of the BiSb film is deteriorated, even if a ferromagnetic layer is formed on the BiSb film, the high spin injection efficiency of the original BiSb film may not be obtained, and the spin Hall angle, that is the SOT characteristics, may be significantly impaired.

### <4. Relationship Between Annealing Treatment, and Crystallinity and Device Characteristics of SOT Electrode Layer>

After the surface planarization treatment 9 of the BiSb film (e.g., the sputtered BiSb film 3a), an intermediate layer 4 may be formed on the BiSb film (e.g., the sputtered BiSb film 3a). Then, an annealing treatment may be performed at a temperature equal to or higher than the melting point of BiSb by a vacuum integrated process. By this annealing treatment, the BiSb film (e.g., the sputtered BiSb film 3a) may be first melted and then crystallized by cooling. By this melting and crystallization process, the etching damage remaining on the surface of the BiSb film (e.g., the sputtered BiSb film 3a) due to the planarization treatment may be repaired, and a good crystal structure may be formed. At this time, the BiSb film (e.g., the sputtered BiSb film 3a) may be annealed while being capped with an intermediate layer, crystallization may proceed while maintaining the flatness obtained by the planarization treatment. The crystal structure of the crystallized BiSb film may depend on the type and crystal structure of the oxide buffer layer, and the type and crystal structure of the intermediate layer. Through this annealing treatment and subsequent cooling (e.g., the melting and crystallization process), the SOT electrode layer 3 may be formed (FIG. 2B).

After the annealing treatment and subsequent cooling in a device structure having the SOT electrode layer 3 between the oxide buffer layer (e.g., the buffer layer 2) and the intermediate layer 4 (e.g., after the melting and crystallization process), experiments were conducted to clarify the crystal orientation and SOT characteristics of BiSb in the SOT electrode layer 3.

### (Characteristic Evaluation of Magnetoresistive Device)

As a simulation test device to evaluate the characteristics of a magnetoresistive device, a device including a stack structure of Si/SiO₂ substrate/TiOₓ (2.5)/TaOₓ (1)/BiSb (10)/Ti (3)/Ta (1)/CoFeB (1)/MgO (3)/Ta (2) (values in parentheses are film thicknesses in nm) was manufactured. Here, the formation of each layer on the Si/SiO₂ substrate was performed by sputtering. In addition, the sputtering of BiSb was performed at room temperature.

After the Ti layer was formed in the stack structure, annealing treatment of the stack structure was performed in a vacuum at about 400° C. for about 60 minutes, and the stack structure after the annealing treatment was left in a vacuum (about 10-6 Pa) for about 1 hour to cool. Next, after each layer (e.g., Ta/CoFeB/MgO/Ta of the stack structure) placed on top of the Ti layer in the stack structure was further formed, post-annealing was performed at 250° C. for 30 minutes. In the manufacture of the simulation test device, surface planarization treatment of BiSb was not performed.

Here, in the simulation test device, the “Si/SiO₂ substrate” may indicate a substrate on which a SiO₂ film is formed on a Si substrate and may correspond to an underlayer (not shown), “TiOₓ/TaOₓ” is a stack structure of a TiOₓ film and a TaOₓ film, and these films may correspond to an oxide buffer layer (e.g., the buffer layer 2), “BiSb” may correspond to the SOT electrode layer 3, “Ti/Ta” may be a stack structure of a Ti film and a Ta film, and these films may correspond to the intermediate layer 4, “CoFeB” may correspond to a “ferromagnetic recording layer (e.g., the first magnetic layer 5)”, and “MgO” may correspond to a “tunnel barrier layer (e.g., the non-magnetic layer 6)”.

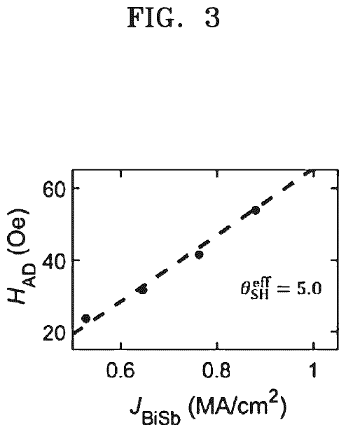

For the simulation test device obtained above, the spin Hall angle was measured by the second harmonic Hall measurement method. In this measurement method, a device that may apply an external magnetic field and an alternating current to a Hall device was used to separate a first harmonic component and a second harmonic component of Hall resistance and perform lock-in measurement. A longitudinal effective magnetic field was calculated from the second harmonic component of the Hall resistance. The spin Hall angle was calculated from the slope of the applied current dependence of the longitudinal effective magnetic field. As a result of the measurement, as shown in FIG. 3, a value of 5.0, which is about two orders of magnitude greater than when a heavy metal film such as W or Ta was used as the SOT electrode layer, was obtained. In addition, in FIG. 3, H_{AD}(Oe) may represent a SOT antidamping effective magnetic field, J_{BiSb} (unit: MA/cm²) may represent the current density flowing inside the BiSb layer, and θ_{SH}^{eff} may represent the spin Hall angle.

In addition, the electrical conductivity of the SOT electrode layer 3 (e.g., the BiSb film) was measured using the simulation test device according to a four-terminal method of the Hall device. The electrical conductivity of the SOT electrode layer 3 was about 0.8×10⁵ Ω⁻¹m⁻¹, which was equivalent to that of heavy metals such as W or Ta. The measurement of the electrical conductivity of the SOT electrode layer 3 was performed as follows. First, the electrical conductivity was measured in the simulation test device. Next, in order to measure the electrical conductivity of the SOT electrode layer 3 in the simulation test device, a stack having a stack structure of the same shape as the simulation test device except that the SOT electrode layer 3 was not present was manufactured, and the electrical conductivity of this stack was measured. Then, the electrical conductivity of the stack having the stack structure of the same shape as the simulation test device except that the SOT electrode layer 3 is absent was subtracted from the electrical conductivity in the simulation test device, and the value obtained by subtracting was taken as the electrical conductivity of the SOT electrode layer 3.

On the other hand, in cases where the stack structure is complex and it is difficult to measure the electrical conductivity of the SOT electrode layer 3 using the method described above, a stack having a simpler stack structure may be used to measure the electrical conductivity of the SOT electrode layer 3 according to the four-terminal method of the Hall device. Specific Examples of this measurement method may include the following methods. Instead of the simulation test device, a stack L1 may be manufactured by stacking an underlayer (not shown), a buffer layer 2, a SOT electrode layer 3, and an intermediate layer 4 in this order, and then the electrical conductivity thereof may be measured. Here, the stack L1 may have a stack structure consisting of a Ta film, which is the intermediate layer 4 in the simulation test device, and each layer arranged below the Ta film, and may be a stack that has undergone annealing treatment and cooling. In addition, a stack L2 having the same shape of stack structure as the stack L1 except that there is no SOT electrode layer 3, may be manufactured and the electrical conductivity thereof may be measured. Here, a value obtained by subtracting the electrical conductivity of the stack L2 from the electrical conductivity of the stack L1 may be used as the electrical conductivity of the SOT electrode layer 3.

### (Evaluation of Crystal Orientation of SOT Electrode Layer)

To evaluate the crystal orientation of the SOT electrode layer, a stack having a stack structure of Si/SiO₂ substrate/TiOx(6)/BiSb(10)/Ti(3)/Pt(0.8)/Co(0.8)/Pt(0.8) (the values in parentheses are film thicknesses in nm) was manufactured. Here, the formation of each layer on the Si/SiO₂ substrate was performed by sputtering. In addition, the sputtering of BiSb was performed at room temperature.

After the Ti layer was formed in the stack structure, annealing treatment of the stack structure was performed in a vacuum at about 400° C. for about 60 minutes, and the stack structure after the annealing treatment was left in a vacuum (about 10-6 Pa) for about 1 hour to cool. Thereafter, each layer (e.g., each layer of Pt/Co/Pt) placed on top of the Ti layer in the stack structure was formed by sputtering, thereby obtaining a stack for evaluating the crystal orientation of the SOT electrode layer. During the manufacture of this stack, the surface planarization treatment of BiSb was not performed.

Here, in the stack for evaluating the crystal orientation of the SOT electrode layer, the “Si/SiO₂ substrate” may represent a substrate on which a SiO₂ film is formed on a Si substrate and may correspond to the underlayer (not shown), “TiOx” may correspond to the oxide buffer layer (e.g., the buffer layer 2), “BiSb” may correspond to the SOT electrode layer 3, “Ti” may correspond to the intermediate layer 4, and “Pt/Co/Pt” may be a stack structure of a Pt film, a Co film, and a Pt film, and these films may correspond to the “ferromagnetic recording layer (e.g., the first magnetic layer 5)”.

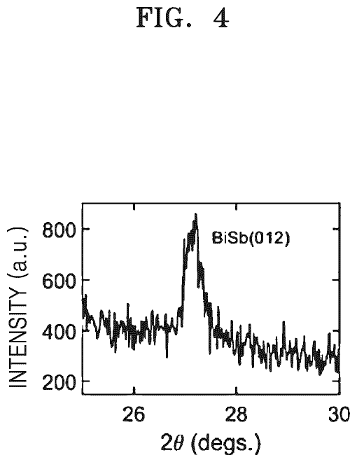

Then, as a result of measuring the crystal orientation of the BiSb film of the stack to evaluate the crystal orientation of the SOT electrode layer by X-ray diffraction, it was confirmed that a good crystal orientation of the BiSb(012) plane direction was obtained (for example, the crystal structure of the BiSb film has a good plane orientation of a crystal plane in a plane parallel to the layer corresponding to the first magnetic layer preferentially oriented to BiSb(012)). The result is shown in FIG. 4.

From the above results, it was confirmed that when the BiSb film (e.g., the sputtered BiSb film 3a) disposed between the oxide buffer layer (e.g., the buffer layer 2) and the intermediate layer 4 is annealed at a temperature higher than the melting point of BiSb and then cooled, the BiSb crystallized with a good crystal orientation after it was once melted. In addition, it was confirmed that this crystallized BiSb film may function as a very good SOT electrode layer 3.

Furthermore, for a stack structure including an oxide buffer layer (e.g., the buffer layer 2)/BiSb film (e.g., the SOT electrode layer 3)/intermediate layer 4/ferromagnetic recording layer (e.g., the first magnetic layer 5)/tunnel barrier layer (e.g., the non-magnetic layer 6)/ferromagnetic reference layer (e.g., the second magnetic layer 7), an MTJ portion located above the SOT electrode layer 3 and the intermediate layer 4 may be etched into a pillar shape using a hard mask, thereby completing the main portion 1 of the SOT-MRAM device of Specific Example 1.

The SOT-MRAM devices manufactured through this process (e.g., the melting and crystallization process) may achieve characteristics superior to conventional SOT-MRAM devices. Accordingly, in the SOT-MRAM device manufactured through this process, the crystal structure of the SOT electrode layer 3 may be such that a plane orientation of a crystal plane in a plane parallel to the first magnetic layer 5 is preferentially oriented to BiSb (012), and excellent characteristics may be obtained, such as the electrical conductivity of about 0.8×10⁵ Ω⁻¹m⁻¹ and the spin Hall angle value of about 5 for the SOT electrode layer 3.

As described above, the surface planarization treatment 9 of the BiSb film was not performed in the simulation test device, but by performing the surface planarization treatment 9 of the BiSb film, further improvement in the characteristics of the magnetoresistive device may be realized. Therefore, according to an example of the magnetoresistive device of Specific Example 1, the electric conductivity of the SOT electrode layer 3 may be at least about 0.8×10⁵ Ω⁻¹m⁻¹, and the electrical conductivity of the SOT electrode layer 3 may exceed about 0.8×10⁵ Ω⁻¹m⁻¹, preferably at least about 1×10⁵ Ω⁻¹m⁻¹. In addition, according to an example of the magnetoresistive device of Specific Example 1, the spin Hall angle may be at least about 5 or more, preferably more than about 5, preferably about at least about 10 or more, more preferably more than about 10.

### Specific Example 2

Hereinafter, the first and third embodiments will be described in more detail with Specific Examples. However, the first and third embodiments are not limited to the Specific Examples below.

In Specific Example 2, it will be described that the SOT characteristics of a magnetoresistive device may be improved by subsequent annealing treatment and cooling when a BiSb film is formed under conditions of sputtering film formation that does not damage flatness. The configuration of the magnetoresistive device (e.g., the SOT-MRAM device) of Specific Example 2 may have the main portion 1 of the configuration illustrated in FIG. 1, similar to the magnetoresistive device of Specific Example 1.

In a method of manufacturing the magnetoresistive device of Specific Example 2, when forming the BiSb film by sputtering on the oxide buffer layer (e.g., the buffer layer 2), the temperature of the substrate (e.g., a stack including an interlayer insulating film and an oxide buffer layer in this order from the bottom) may be cooled below room temperature, thereby suppressing the granular growth of BiSb and forming a thin film in a state close to amorphous (e.g., the amorphous sputtered BiSb film 3b). By suppressing the granular growth of BiSb in this way, a sputtered film may be formed with a surface roughness measured by micro-area analysis, e.g., the arithmetic average roughness Ra, of 0.5 nm or less. In addition, in Specific Example 2, the surface planarization treatment of the BiSb film is not performed.

The reason why the high spin Hall angle may be obtained by using the BiSb film, which is a topological insulator, as the SOT electrode layer may be considered to be due to the surface current specific to topological insulators, which is caused by the crystal structure and electronic structure of the BiSb film. When the BiSb film is in an amorphous state with poor crystallinity, the spin Hall angle and ultimately the SOT characteristics may be significantly damaged.

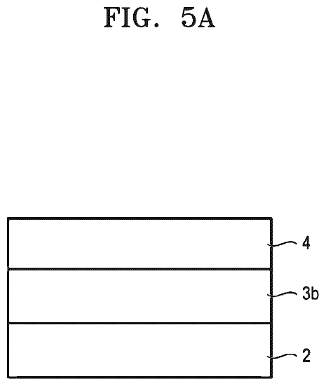

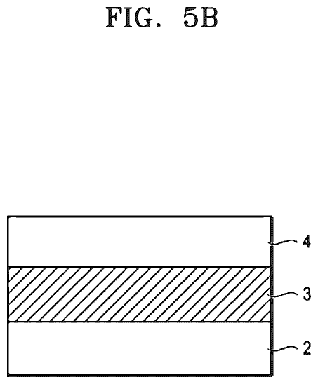

Thus, the intermediate layer 4 may be formed on the BiSb film (e.g., the amorphous sputtered BiSb film 3b) (FIG. 5A). Then, an annealing treatment may be performed at a temperature equal to or higher than the melting point of BiSb by a vacuum integrated process. By this annealing treatment, the BiSb film (e.g., the amorphous sputtered BiSb film 3b) may be first melted and then crystallized by cooling. The BiSb film may change from an amorphous state to a film with good crystal orientation. At this time, the BiSb film (e.g., the amorphous sputtered BiSb film 3b) may be annealed while being capped with the intermediate layer 4, crystallization may proceed while maintaining the flatness during film formation in the amorphous state. The crystal structure of the crystallized BiSb film may depend on the type and crystal structure of the oxide buffer layer (e.g., the buffer layer 2) and the type and crystal structure of the intermediate layer 4. Through this annealing treatment and subsequent cooling (e.g., the melting and crystallization process), the SOT electrode layer 3 may be formed (FIG. 5B).

A method of manufacturing the magnetoresistive device of Specific Example 2 may be the same as the method of manufacturing the magnetoresistive device of Specific Example 1, except for the above-mentioned part in the process of forming the SOT electrode layer 3. Therefore, the magnetoresistive device of Specific Example 2 may have a configuration of the main portion 1 substantially the same as the magnetoresistive device of Specific Example 1. Accordingly, the magnetoresistive device of Specific Example 2 may be expected to have the same good characteristics as the magnetoresistive device of Specific Example 1.

<Magnetoresistive Device with SOT Electrode Layer Located Above MTJ Device and Method of Manufacturing the Same>

### Fourth and Fifth Embodiments

A fourth embodiment of the inventive concepts relates to a magnetoresistive device, the magnetoresistive device may include: a magnetic tunnel junction (MTJ) device; an intermediate layer provided on a first magnetic layer of the MTJ device; a SOT electrode layer that may apply spin-orbit torque (SOT) to the first magnetic layer by flowing a current therethrough; and a cap layer including at least one compound of oxide, nitride and oxynitride that are provided on the SOT electrode layer; wherein the MTJ device includes a second magnetic layer, a non-magnetic layer provided on the second magnetic layer, and the first magnetic layer provided on the non-magnetic layer, the SOT electrode layer includes BiSb, and a crystal structure of the SOT electrode layer is such that the plane orientation of a crystal plane in a plane parallel to the first magnetic layer is preferentially oriented to BiSb(012), the magnetoresistive device includes a pillar structure including the MTJ device and the intermediate layer, the SOT electrode layer includes a first portion α disposed on the intermediate layer in the pillar structure, and a second portion β disposed on a member that does not constitute the pillar structure, the first portion α and the second portion β exist integrally, and the magnetoresistive device satisfies at least one of the following (1) and the following (11).
(II) The first portion α has a film thickness greater than that of the second portion β;
(II) The first portion α and the second portion β exist continuously in terms of crystallography.

A fifth embodiment of the inventive concepts relates to a method of manufacturing a magnetoresistive device, the magnetoresistive device may include: a magnetic tunnel junction (MTJ) device; an intermediate layer provided on a first magnetic layer of the MTJ device; a SOT electrode layer that may apply spin-orbit torque (SOT) to the first magnetic layer by flowing a current therethrough; and a cap layer including at least one compound of oxide, nitride and oxynitride that are provided on the SOT electrode layer; wherein the MTJ device includes a second magnetic layer, a non-magnetic layer provided on the second magnetic layer, and the first magnetic layer provided on the non-magnetic layer, the magnetoresistive device includes a pillar structure including the MTJ device and the intermediate layer, the SOT electrode layer includes a first portion α disposed on the intermediate layer in the pillar structure, and a second portion β disposed on a member that does not constitute the pillar structure, the first portion α and the second portion β exist integrally, and the SOT electrode includes BiSb, and the method of manufacturing the magnetoresistive device includes forming the SOT electrode according to a method including the following (i), the following (ii), the following (iii), the following (iv), the following (v), the following (vi), and the following (vii).
(II) forming the MTJ device, the intermediate layer, and a first preliminary SOT electrode layer including BiSb in this order;
(ii) etching a stack structure portion including the MTJ device, the intermediate layer, and the first preliminary SOT electrode layer into a pillar shape to form a preliminary pillar structure including the MTJ device, the intermediate layer, and the first preliminary SOT electrode layer;
(iii) forming at least one film of a protective film and an interlayer insulating film around side and upper surfaces of the preliminary pillar structure;
(iv) exposing a portion of the first preliminary SOT electrode layer by performing at least one treatment of planarizing and thinning the at least one film of the protective film and the interlayer insulating film;
(v) forming a second preliminary SOT electrode layer including BiSb, on a surface of the first preliminary SOT electrode layer and on the at least one film of the protective film and the interlayer insulating film, in which the first preliminary SOT electrode layer and the second preliminary SOT electrode layer are connected to form a third preliminary SOT electrode layer;
(vi) forming the cap layer on the third preliminary SOT electrode layer; and
(vii) after forming the cap layer, performing crystallization of BiSb by annealing the third preliminary SOT electrode layer at a temperature of at least a melting point of BiSb and then cooling.

Hereinafter, a device structure exhibiting good SOT characteristics while having a structure in which a SOT electrode layer is located above the MTJ device in the fourth and fifth embodiments will be described.

In addition, in the magnetoresistive device according to the fourth and fifth embodiments, the first portion α disposed on the intermediate layer in the pillar structure of the SOT electrode layer and the second portion β disposed on a member that does not constitute the pillar structure of the SOT electrode layer may represent different portions of the SOT electrode layer. Therefore, the second portion β, which is usually disposed on the member that does not form the pillar structure of the SOT electrode layer, may not be disposed on the pillar structure. The SOT electrode layer may or may not include portions other than the first portion α and the second portion β.

### (Device Configuration)

In the magnetoresistive device of the fourth and fifth embodiments, the first portion α, which is disposed on the intermediate layer in the pillar structure of the SOT electrode layer, and the second portion β, which is disposed on the member that does not constitute the pillar structure of the SOT electrode layer, may preferably exist integrally.

The magnetoresistive device in the fourth embodiment may preferably satisfy the following (I) and (II). In the fifth embodiment, the magnetoresistive device may preferably satisfy at least one of the following (I) and the following (II), and more preferably, satisfy the (I) and the (II).
(II) The first portion α, which is disposed on the intermediate layer in the pillar structure of the SOT electrode layer, may have a film thickness greater than that of the second portion β, which is disposed on the member that does not form the pillar structure of the SOT electrode layer.
(II) The first portion α, which is disposed on the intermediate layer in the pillar structure of the SOT electrode layer and the second portion β, which is disposed on the member that does not form the pillar structure of the SOT electrode layer, may exist continuously in terms of crystallography.

In addition, the fact that the first portion α, which is disposed on the intermediate layer in the pillar structure of the SOT electrode layer and the second portion β, which is disposed on the member that does not form the pillar structure of the SOT electrode layer, may exist continuously in terms of crystallography, may be confirmed by cross-sectional transmission electron microscopy (TEM) analysis and/or cross-sectional scanning TEM (STEM) analysis as a disassembly investigation. In addition, details of the evaluation method will be described in the Specific Examples described below.

In at least one embodiment, the magnetoresistive device may further include an underlayer, or may not include the underlayer. The magnetoresistive device may preferably include the underlayer. In at least one embodiment, the magnetoresistive device may include the underlayer, and preferably, the second magnetic layer may be provided on the underlayer, and more preferably, the second magnetic layer may be provided directly on the underlayer. The SOT electrode layer may be preferably provided immediately above the intermediate layer. The intermediate layer may be preferably provided on the first magnetic layer, and more preferably, the intermediate layer may be provided directly on the first magnetic layer. In at least one embodiment, the cap layer may be provided directly on the SOT electrode layer, and that the SOT electrode layer may be preferably provided directly on the intermediate layer. The MTJ device may include a second magnetic layer, a non-magnetic layer provided directly on the second magnetic layer, and a first magnetic layer provided on the non-magnetic layer. The MTJ device may be provided on the underlayer. The intermediate layer may be preferably provided directly on the MTJ device, and more preferably, the intermediate layer may be provided directly on the MTJ device and the intermediate layer may be provided directly on the first magnetic layer. On the other hand, the stack structure of the magnetoresistive device in the fourth to fifth embodiments is not limited thereto.

In at least one embodiment, the magnetoresistive device may further include the underlayer, and the MTJ device may be provided on the underlayer, and the first portion α disposed on the intermediate layer in the pillar structure of the SOT electrode layer and the second portion β disposed on the member that does not constitute the pillar structure of the SOT electrode layer may preferably exist integrally. At this time, the SOT electrode layer may have a shape having a convex portion facing the underlayer, and an underlayer-side surface of the SOT electrode layer in the first portion α, which is disposed on the intermediate layer in the pillar structure of the SOT electrode layer, may be preferably arranged closer to the underlayer than the underlayer-side surface of the SOT electrode layer in the second portion β, which is disposed on the member that does not form the pillar structure of the SOT electrode layer.

In the fourth and fifth embodiments, at least a portion of the member that does not constitute the pillar structure may preferably include an interlayer insulating film, and more preferably, the at least a portion of the member may include an interlayer insulating film and a protective film. In at least one embodiment, the SOT electrode layer may preferably include the first portion α disposed on the intermediate layer in the pillar structure and a portion disposed on the interlayer insulating film. At this time, the SOT electrode layer may further include a portion disposed on the protective layer. Therefore, the second portion β disposed on the member that does not constitute the pillar structure of the SOT electrode layer may preferably include a portion disposed on the interlayer insulating film of the SOT electrode layer, and may include the portion disposed on the interlayer insulating film and a portion disposed on the protective layer of the SOT electrode layer. The SOT electrode layer may or may not include portions other than the first portion α and the second portion β.

### (Underlayer, Intermediate Layer and MTJ Device)

The descriptions of the underlayer, intermediate layer, MTJ device, first magnetic layer, non-magnetic layer, and second magnetic layer in the fourth and fifth embodiments may be the same as (or substantially similar to) the descriptions of these layers in the first to third embodiments, respectively.

### (Cap Layer)

The magnetoresistive device in the fourth to fifth embodiments may include a cap layer including at least one compound of oxide, nitride, and oxynitride. The cap layer may be the same as (or substantially similar to) the buffer layer in the first to third embodiments, except that its position is different. In at least one embodiment, the cap layer may have a crystal structure that may control the crystal orientation of the SOT electrode layer, which is formed by melting and subsequent crystallization of BiSb.

The ratio of the electrical conductivity (Ω⁻¹m⁻¹) of the cap layer to the electrical conductivity (Ω⁻¹m⁻¹) of the SOT electrode layer (e.g., the electrical conductivity of the cap layer/the electrical conductivity of the SOT electrode layer) may be less than about 1, and may be about 0.1 or less (the lower limit thereof is more than 0). In these ranges, the spin Hall angle may become larger. A method of measuring the electrical conductivity of the SOT electrode layer is as described above. A method of measuring the electrical conductivity of the cap layer may be the same as (or substantially similar to) the method of measuring the electrical conductivity of the SOT electrode layer, except that a measurement target is changed from the SOT electrode layer to the buffer layer.

Metals in the metal oxide, the metal nitride, and the metal oxynitride may include, for example, Ta, Ti, Mg, Al, Mn, or Fe, etc. When the cap layer contains oxide, the oxide may be one type alone, or may be used in combination of two or more types. When the cap layer contains nitride, the nitride may be one type alone, or may be used in combination of two or more types. When the cap layer contains oxynitride, the oxynitride may be one type alone, or may be used in combination of two or more types. The cap layer may include at least one compound of metal oxide, metal nitride and metal oxynitride, more preferably include oxide, more preferably include metal oxide, and still more preferably include an oxide of at least one metal of Ta, Ti, Mg, Al, Mn and Fe. Here, the oxide may include a complex oxide.

The cap layer may have a significant influence on the crystal structure of the SOT electrode layer after annealing and subsequent cooling (e.g., after melting and crystallization processes) as described in the Specific Examples described below. Here, when the crystal structure of the SOT electrode layer is preferentially oriented to BiSb(012) (e.g., when BiSb in the SOT electrode layer is preferentially oriented in the (012) plane orientation), a very large spin Hall angle may be obtained. Therefore, after the SOT electrode layer undergoes annealing treatment and subsequent cooling (e.g., after undergoing a melting and crystallization process), the cap layer that is likely to have a crystal orientation of BiSb(012) may be desirable. Examples of oxides included in such a cap layer may include TaOₓ, TiOₓ, MgO, MgAl₂O₄, MnO, or FeO, etc. Thus, the cap layer may preferably include at least one metal oxide of TaOₓ, TiOₓ, MgO, MgAl₂O₄, MnO, and FeO, and more preferably include at least one metal oxide of TaOₓ and TiOₓ.

The cap layer may be preferably a sputtered film of at least one compound of oxide, nitride, and oxynitride.

When the cap layer includes a metal element and at least one element of oxygen (O) and nitrogen (N), the total content of the metal element and the at least one element of oxygen and nitrogen in the cap layer may be 50 atomic percent or more, 60 atomic percent or more, 80 atomic percent or more, 90 atomic percent or more, 95 atomic percent or more, 99 atomic percent or more, and 100 atomic percent (the upper limit is 100 atomic percent). The cap layer may be preferably included the metal element (preferably at least one element of Ta, Ti, Al, Mg, and Fe) and the at least one element of oxygen and nitrogen. The cap layer may be preferably included the metal element (preferably at least one element of Ta, Ti, Al, Mg, and Fe), the at least one element of oxygen and nitrogen, and an element of an inevitable impurity. The content of elements in the cap layer may be evaluated by XPS, for example. In addition, when analyzing a microscopic area from a cross-section of a stack structure, the content of elements in the cap layer may be evaluated by TEM-EDS, for example.

The cap layer may include a single layer or may include a stack structure of two or more layers. The cap layer may preferably include a stack structure including two or more layers with different compositions. The cap layer may preferably have a stack structure consisting of two or more layers with different compositions. For example, in a stack structure of TiOₓ film and TaOₓ film, each layer may have a different role, which may further improve the characteristics of the magnetoresistive device. In this case, the TiOₓ film may have the function of suppressing the deterioration of electrical conductivity due to diffusion of oxygen from the interlayer insulating film such as SiO₂ to the SOT electrode layer. On the other hand, the TaOₓ film may be suitable for promoting the crystal orientation of BiSb(012) in the SOT electrode layer. Furthermore, it is considered that when the TaOₓ film is formed through the TiOₓ layer rather than being formed as a single layer below the interlayer insulating film such as SiO₂, the function of promoting the crystal orientation of BiSb(012) of the SOT electrode layer by the TaOₓ film may be further enhanced. Thus, the cap layer having a stack structure of two or more layers with different compositions, such as a stack structure of the TiOₓ film and the TaOₓ film, may be more suitable for increasing the spin Hall angle because the cap layer may be less likely to deteriorate the electrical conductivity of the SOT electrode layer after annealing treatment and subsequent cooling (for example, after a melting and crystallization process) and the cap layer may promote the crystal orientation of BiSb(012) of the SOT electrode layer.

When the cap layer has the stack structure including two or more layers with different compositions, each of the two or more layers with different compositions may equally apply the description with respect to the cap layer.

When the cap layer has the stack structure including two or more layers with different compositions, the ratio of the electrical conductivity (Ω⁻¹m⁻¹) of each layer constituting the cap layer to the electrical conductivity (Ω⁻¹m⁻¹) of the SOT electrode layer (e.g., electrical conductivity of each layer constituting the cap layer/electrical conductivity of the SOT electrode layer) may be less than about 1, and may be preferably about 0.1 or less (the lower limit thereof is more than 0). In these ranges, the spin Hall angle may become larger. A method of measuring the electrical conductivity of the SOT electrode layer will be described below. The method of measuring the electrical conductivity of each layer constituting the cap layer may be the same as the method of measuring the electrical conductivity of the SOT electrode layer, except that the measurement target is changed from the SOT electrode layer to each layer constituting the cap layer.

When the cap layer has the stack structure including two or more layers with different compositions, each of the two or more layers with different compositions may include at least one compound of oxide, nitride, and oxynitride. The two or more layers with different compositions may include at least one compound of metal oxide, metal nitride, and metal oxynitride. When any one or all layers of the two or more with different compositions include oxide, the oxide may be one type alone or two or more types used in combination. When any one or all layers of the two or more with different compositions include nitride, the nitride may be one type alone or two or more types used in combination. When any one or all layers of the two or more with different compositions include oxynitride, the oxynitride may be one type alone or two or more types used in combination. All of the two or more layers with different compositions may preferably include oxide, and they may more preferably include metal oxide. In at least one embodiment, each of the two or more layers with different compositions may independently include an oxide of at least one metal of Ta, Ti, Mg, Al, Mn and Fe. Here, the oxide may include a complex oxide. In at least one embodiment, each of the two or more layers with different compositions may independently include at least one metal oxide of TaOₓ, TiOₓ, MgO, MgAl₂O₄, MnO and FeO, and it is more preferable that they include at least one metal oxide of TaOₓ and TiOₓ.

When the cap layer has the stack structure including two or more layers with different compositions, each of the two or more layers with different compositions may independently include a sputtered film of at least one compound of oxide, nitride, and oxynitride. It is particularly preferable that the cap layer may include the sputtered film of TiOₓ or the sputtered film of TaOₓ.

When the cap layer has the stack structure including the two or more layers with different compositions, and the two or more layers with different compositions include a metal element and at least one element of oxygen and nitrogen, the total content of the metal element and the at least one element of oxygen and nitrogen in each of the two or more layers may be about 50 atomic percent or more, 60 atomic percent or more, 80 atomic percent or more, 90 atomic percent or more, 95 atomic percent or more, 99 atomic percent or more, and 100 atomic percent (the upper limit is 100 atomic percent). It is preferable that all of the two or more layers with different compositions may be composed of the metal element (preferably at least one element of Ta, Ti, Al, Mg and Fe) and at least one element of oxygen and nitrogen. It is preferable that all of the two or more layers with different compositions may be composed of the metal element (preferably at least one element of Ta, Ti, Al, Mg and Fe), at least one element of oxygen and nitrogen, and an element of an inevitable impurity. The method of evaluating the element content in each of the two or more layers may be the same as the method of evaluating the element content in the cap layer.

A film thickness of the cap layer (the film thickness of each layer when the cap layer is the stack structure of the two or more layers) may be at least about 0.1 nm but not more than about 25 nm, more preferably at least about 0.5 nm but not more than about 15 nm, and even more preferably at least about 1 nm but not more than about 10 nm.

### (Protective Film)

A composition of the protective film may include, for example, SiN, SiCN, SiON, SiC, amorphous carbon, SiOC, and other dielectric materials. The material of the protective film may be one type alone, or two or more types may be used in combination. The protective film may preferably include at least one of SiN, SiCN, SiON, SiC, amorphous carbon, SiOC and other low-k materials.

### (Interlayer Insulating Film)

A composition of the interlayer insulating film may include, for example, SiN, SiO₂, SiCN, SiON, SiC, amorphous carbon, SiOC, and other dielectric materials. The material of the interlayer insulating film may be one type alone, or two or more types may be used in combination. The interlayer insulating film may preferably include at least one of SiN, SiCN, SiO₂, SiON, SiC, amorphous carbon, SiOC and other low-k materials.

(Layers Other than Those Described Above)

The magnetoresistive device in the fourth to fifth embodiments may further include layers and/or other members other than those described above.

### (Device Characteristics)

In the magnetoresistive device of the fourth to fifth embodiments, the value of the spin Hall angle, which is the conversion efficiency from current to spin current, may be preferably at least about 5, more preferably greater than 5, and even more preferably more than 10. The value of the spin Hall angle may be measured by a second harmonic Hall measurement method. In at least one embodiment, the electrical conductivity of the SOT electrode layer may be preferably at least about 0.8×10⁵ Ω⁻¹m⁻¹ (more preferably greater than about 0.8×10⁵ Ω⁻¹m⁻¹, and even more preferably greater than about 1×10⁵Ω⁻¹m⁻¹), and the value of the spin Hall angle, which is the conversion efficiency from current to spin current in the magnetoresistive device, may be at least about 5 (more preferably greater than about 5, and even more preferably greater than about 10). In at least one embodiment, the crystal structure of the SOT electrode layer may preferably be such that the plane orientation of the crystal plane in a plane parallel to the first magnetic layer is preferentially oriented to BiSb(012), the electrical conductivity of the SOT electrode layer may be preferably at least about 0.8×10⁵ Ω⁻¹m⁻¹ (more preferably greater than about 0.8×10⁵ Ω⁻¹m⁻¹, and even more preferably greater than about 1×10⁵θ⁻¹m⁻¹), and the value of the spin Hall angle, which is the conversion efficiency from current to spin current in the magnetoresistive device, may be at least about 5 (more preferably greater than about 5, and even more preferably greater than about 10). The crystal structure of the SOT electrode layer and the method of measuring the electrical conductivity of the SOT electrode layer are the same as those described for the SOT electrode layer.

### (Method of Manufacturing a Magnetoresistive Device)

A manufacturing method of the magnetoresistive device in the fourth embodiment may include a manufacturing method according to the fifth embodiment. The magnetoresistive device manufactured in the fifth embodiment may be preferably the magnetoresistive device according to the fourth embodiment. However, the magnetoresistive device manufactured in the fifth embodiment is not limited thereto.

In at least one embodiment, a method of forming each layer of the magnetoresistive device may be the same as (or substantially similar to) the method of forming each layer, described with respect to the first to third embodiments.

The temperature at the time of sputtering film formation for forming each layer in the fifth embodiment may be the same as the temperature at the time of sputtering film formation described in the second embodiment.

The manufacturing method according to the fifth embodiment may include forming the MTJ device, the intermediate layer, and the first preliminary SOT electrode layer including BiSb in this order, as in (i) above. When forming the MTJ device, the intermediate layer, and the first preliminary SOT electrode layer in this order, the intermediate layer, and the first preliminary SOT electrode layer may be preferably sequentially formed. When forming the MTJ device, the second magnetic layer, the non-magnetic layer, and the first magnetic layer may be preferably formed in this order, and more preferably, the second magnetic layer, the non-magnetic layer, and the first magnetic layer may be sequentially formed. A method of forming the first preliminary SOT electrode layer including BiSb may be preferably formed by a method including sputtering film formation. A method of forming the MTJ device, the intermediate layer, and the first preliminary SOT electrode layer including BiSb may be preferably formed by a method including sputtering film formation.

In at least one embodiment, the method of manufacturing the magnetoresistive device may preferably further include performing a post-annealing treatment after forming the MTJ device, the intermediate layer, and the first preliminary SOT electrode layer. The temperature of the post-annealing treatment in the fifth embodiment may be the same as (or substantially similar to) the temperature of the post-annealing treatment in the second and third embodiments. The time of the post-annealing treatment in the fifth embodiment may be the same as the time of the post-annealing treatment in the second and third embodiments.

A method of etching the stack structure including the MTJ device, the intermediate layer, and the first preliminary SOT electrode layer may include the following method may. First, a hard mask layer may be formed on the first preliminary SOT electrode layer, and the hard mask layer may be dry etched to fit the processing shape (e.g., a shape of the intended pillar structure). Thereafter, the stack structure including the MTJ device, the intermediate layer, and the first preliminary SOT electrode layer may be etched into the pillar shape by dry etching using the processed hard mask layer. The hard mask layer may be preferably provided on an uppermost surface of the stack structure including the MTJ device, the intermediate layer, and the first preliminary SOT electrode layer. The hard mask layer may be preferably provided to constitute an uppermost layer in a stack structure including the MTJ device, the intermediate layer, and the first preliminary SOT electrode layer and the hard mask layer. The material constituting the hard mask layer may include, for example, MgO, Ta, W, Mo, Ru, TiN, alloys thereof, or combinations thereof. A method of dry etching may include, for example, ion milling and reactive ion etching (RIE). When etching the stack structure including an MTJ device, an intermediate layer, and a first preliminary SOT electrode layer into the pillar shape, the MTJ device, the intermediate layer, and the first preliminary SOT electrode layer may be preferably etched by one etching process.

In the fifth embodiment, the MTJ device, the intermediate layer, and the first preliminary SOT electrode layer may be etched into the pillar shape as in (ii) above, to form a preliminary pillar structure including the MTJ device, the intermediate layer, and the first preliminary SOT electrode layer. The preliminary pillar structure may preferably further include a hard mask layer. By forming the preliminary pillar structure, the pillar structure including an MTJ device and the intermediate layer may be preferably formed from the preliminary pillar structure. The preliminary pillar structure may preferably include the pillar structure including the MTJ device and the intermediate layer. In addition, when a stack structure including the MTJ device, the intermediate layer, and the first preliminary SOT electrode layer exists on the underlayer, the underlayer may not be preferably etched.

In the fifth embodiment, at least one film of the protective film and the interlayer insulating film may be formed around side and upper surfaces of the preliminary pillar structure as in (iii) above. At this time, the preliminary pillar structure may preferably further include a hard mask layer. Here, forming the film around the side and upper surfaces of the preliminary pillar structure may indicate that the film may be formed so as to directly contact the side and/or upper surfaces of the preliminary pillar structure, or the film may be formed so as not to directly contact the side and/or upper surfaces of the preliminary pillar structure. In at least one embodiment, at least one film of the protective film and the interlayer insulating film may be preferably formed to cover the side and upper surfaces of the preliminary pillar structure. Here, the (iii) above may include the following (iii-1) and the following (iii-2):
(iii-1) forming the protective film to cover the side and upper surfaces of the preliminary pillar structure.
(iii-2) forming the interlayer insulating film to cover the side and upper surfaces of the preliminary pillar structure on which the protective film is formed.

The total film thickness of the protective film and the interlayer insulating film (when only one film exists, its (total) film thickness) may be greater than the total film thickness from the second magnetic layer to the hard mask layer. When the underlayer exists, the total film thickness of the protective film and the interlayer insulating film (when only one film is present, a (total) film thickness) may be preferably greater than the value of the height from the surface of the underlayer to the hard mask layer. By setting the total film thickness of the protective film and the interlayer insulating film (when only one film exists, a (total) film thickness) in this way, a structure in which the preliminary pillar structure may be buried inside the at least one film of the protective film and the interlayer insulating film, may be obtained.

Thereafter, as in (iv) above, at least one treatment of planarization and thinning of film may be performed on the at least one film of the protective film and the interlayer insulating film, thereby exposing a portion of the first preliminary SOT electrode layer. In at least one embodiment, by performing the at least one treatment of planarization and thinning of film on the interlayer insulating film, a portion of the first preliminary SOT electrode layer may be preferably exposed. At this time, in addition to the interlayer insulating film, by performing the at least one treatment of planarization and thinning of film on the protective layer, a portion of the first preliminary SOT electrode layer may be exposed. A method of the at least one treatment of planarization and thinning of film may include, for example, chemical mechanical polishing (CMP) treatment, selective etching, or combinations thereof. As at least one example, by performing an etch-back process by selective etching after the at least one treatment of planarization and thinning of film, there may be a method of thinning the at least one film of the protective film and the interlayer insulating film until the height of the at least one film is lower than an upper surface of the first preliminary SOT electrode layer and higher than a lower surface of the first preliminary SOT electrode layer. At this time, the at least one film of the protective film and the interlayer insulating film may be thinned to a height that is lower than the upper surface of the first preliminary SOT electrode layer and also higher than the lower surface of the first preliminary SOT electrode layer.

The hard mask layer may be removed from the pillar structure by selective etching. By appropriately selecting a dry etching gas in selective etching, the hard mask layer may be etched away.

Thereafter, as in (v) above, a second preliminary SOT electrode layer including BiSb may be formed on a surface of the first preliminary SOT electrode layer and on the at least one film of the protective film and the interlayer insulating film, thereby connecting the first preliminary SOT electrode layer to the second preliminary SOT electrode layer. In at least one embodiment, by forming the second preliminary SOT electrode layer including BiSb on the surface of the first preliminary SOT electrode layer and on the interlayer insulating film, the first preliminary SOT electrode layer may be preferably connected to the second preliminary SOT electrode layer. At this time, in addition to the surface of the first preliminary SOT electrode layer and the interlayer insulating film, the second preliminary SOT electrode layer including BiSb may be formed on the protective layer. In addition, as a result of the (v) above, a portion of the first preliminary SOT electrode layer may be exposed. In addition, in the (v) above, a second non-SOT electrode layer may be formed on at least a portion of a surface of exposed portion of the first preliminary SOT electrode layer and on the interlayer insulating film. A second preliminary SOT electrode layer including BiSb may be formed on at least one surface of an upper surface and a side surface of the first preliminary SOT electrode layer and on the interlayer insulating film. Among these, by forming the second preliminary SOT electrode layer including BiSb on the surface of the first preliminary SOT electrode layer and on the interlayer insulating film, the first preliminary SOT electrode layer may be preferably connected to the second non-SOT electrode layer. Thus, a third SOT electrode layer including the first preliminary SOT electrode layer and the second non-SOT electrode layer may be formed. In at least one embodiment, a second preliminary SOT electrode layer including BiSb may be preferably formed directly on the first preliminary SOT electrode layer and on the protective film and the interlayer insulating film. A method of forming the second preliminary SOT electrode layer including BiSb may include formed by a method including sputtering film formation of a material including BiSb. A magnetoresistive device manufactured by connecting the first preliminary SOT electrode layer to the second preliminary SOT electrode layer may satisfy at least one of (I) and (II) above.

When forming the second preliminary SOT electrode layer by sputtering film formation of a material including BiSb directly on the first preliminary SOT electrode layer and on the interlayer insulating film (e.g. directly on the first preliminary SOT electrode layer and on the protective film and the interlayer insulating film), there may be cases where the third preliminary SOT electrode layer swells after the pillar structure. In such a case, at least one treatment of planarization and thinning of film may be preferably performed on the third preliminary SOT electrode layer. The method of the at least one treatment of planarization and thinning of film may include, for example, CMP treatment, selective etching, or combinations thereof.

A manufacturing method according to the fifth embodiment may include forming a cap layer on the third preliminary SOT electrode layer, as in (vi) above. In at least one embodiment, after forming the cap layer on the third preliminary SOT electrode layer, dry etching processing may be preferably performed on the third preliminary SOT electrode layer to have an SOT wiring shape using a resistor mask or the like. In at least one embodiment, a structure obtained by forming the protective film and the interlayer insulating film on the third preliminary SOT electrode layer processed into the SOT wiring shape may be used as the main portion of the magnetoresistive device.

In the fifth embodiment, as in (vii) above, after forming the cap layer, crystallization of BiSb by annealing the third preliminary SOT electrode layer (e.g., a preliminary SOT electrode layer annealing treatment) at the temperature of at least the melting point of BiSb and then cooling may be performed, thereby obtaining the SOT electrode layer from the third preliminary SOT electrode layer.

The temperature of the annealing treatment (e.g., the preliminary SOT electrode layer annealing treatment) in the fifth embodiment may be the same as or substantially similar to the temperature of the annealing treatment (e.g., the SOT electrode layer annealing treatment) in the second and third embodiments. The time of the annealing treatment (e.g., the preliminary SOT electrode layer annealing treatment) in the fifth embodiment may be the same as the time of the annealing treatment (e.g., the SOT electrode layer annealing treatment) in the second and third embodiments.

A description of the cooling method and conditions in the fifth embodiment may be the same as (or substantially similar to) the description of the cooling method and conditions in the second and third embodiments.

In at least one embodiment, the method of manufacturing the magnetoresistive device may further include operations and/or processes other than those described above.

According to the fifth embodiment, the magnetoresistive device in which the SOT electrode layer may be disposed over the MTJ device can be manufactured without deteriorating the good SOT switching characteristics inherent in the SOT electrode layer including BiSb, so that a significant improvement in the characteristics of the magnetoresistive device can be expected.

According to the example of the fourth and fifth embodiments, a high-performance SOT-MRAM device may be realized by increasing the write efficiency of the SOT device and improving the read efficiency of the MTJ device at the same time.

### Specific Example 3

Hereinafter, the fourth and fifth embodiments will be described in more detail with Specific Examples. However, the fourth and fifth embodiments are not limited to the Specific Examples below.

In Specific Example 3, a device structure in which degradation of SOT characteristics caused by processing damage is improved for an SOT-MRAM device having a BiSb film as an SOT electrode layer on an upper side of an MTJ device, and a method of manufacturing the SOT-MRAM device having such a device structure will be described.

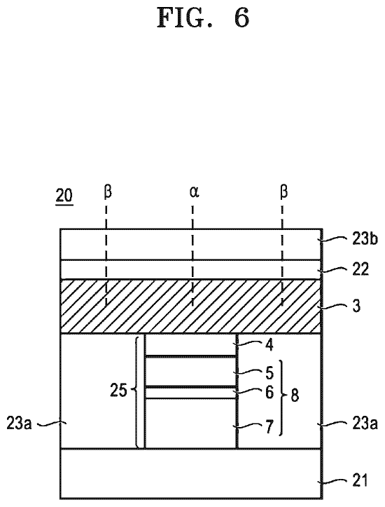

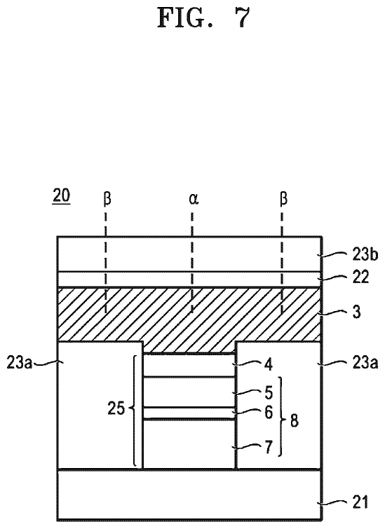

An example of a main portion 20 of a magnetoresistive device (e.g., an SOT-MRAM device) described in Specific Example 3 is illustrated in FIGS. 6 and 7, respectively. A main portion 20 of the magnetoresistive device illustrated in FIGS. 6 and 7 may include a stack structure including, from the bottom, a base electrode 21, a ferromagnetic reference layer (e.g., a second magnetic layer 7), a tunnel barrier layer (e.g., a non-magnetic layer 6), a ferromagnetic recording layer (e.g., a first magnetic layer 5), an intermediate layer 4, a BiSb film (e.g., an SOT electrode layer 3), and an oxide cap layer (e.g., a cap layer 22) on an interlayer insulating film (not shown) such as SiO₂. That is, the main portion 20 of the magnetoresistive device illustrated in FIGS. 6 and 7 may include the stack structure including the interlayer insulating film (not shown) such as SiO₂/the base electrode 21/the ferromagnetic reference layer (e.g., the second magnetic layer 7)/the tunnel barrier layer (e.g., the non-magnetic layer 6)/the ferromagnetic recording layer (e.g., the first magnetic layer 5)/the intermediate layer 4/the BiSb film (e.g., the SOT electrode layer 3)/the oxide cap layer (e.g., the cap layer 22). Here, an underlayer in these magnetoresistive devices may include the interlayer insulating film (not shown) and the base electrode 21.

In the main portion 20 of the magnetoresistive device illustrated in FIGS. 6 and 7, the MTJ device 8, which is composed of the ferromagnetic recording layer (e.g., the second magnetic layer 7)/the tunnel barrier layer (e.g., the non-magnetic layer 6)/the ferromagnetic reference layer (e.g., the first magnetic layer 5), and the intermediate layer 4 may be patterned in a pillar shape to form a pillar structure 25. In the main portion 20 of these magnetoresistive devices, the BiSb film (e.g., the SOT electrode layer 3) may have a shape processed into a wiring shape that extends laterally. Additionally, the main portion 20 of these magnetoresistive devices may include an interlayer insulating film 23b on the oxide cap layer (e.g., the cap layer 22).

In the magnetoresistive devices illustrated in FIGS. 6 and 7, a portion of the BiSb film (e.g., the SOT electrode layer) that contacts the intermediate layer 4 may have the same planar shape as the pillar structure 25.

In the magnetoresistive devices illustrated in FIGS. 6 and 7, the first portion α of the BiSb film (e.g., the SOT electrode layer 3), which is arranged on the intermediate layer 4 in the pillar structure 25, and the second portion β of the BiSb film (e.g., the SOT electrode layer 3), which is arranged on a member (here, a protective film (not shown) and an interlayer insulating film 23a) that does not constitute the pillar structure 25, may exist integrally.

In the magnetoresistive device illustrated in FIGS. 7, the first portion α of the BiSb film (e.g., the SOT electrode layer 3), which is arranged on the intermediate layer 4 in the pillar structure 25, may have a film thickness greater than the second portion β of the BiSb film (e.g., the SOT electrode layer 3), which is arranged on a member (here, a protective film (not shown) and an interlayer insulating film 23a) that does not constitute the pillar structure 25, so that the BiSb film (e.g., the SOT electrode layer 3) may have a structure with a convex portion on a lower side thereof.

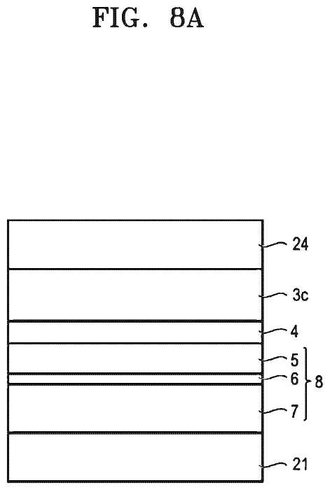

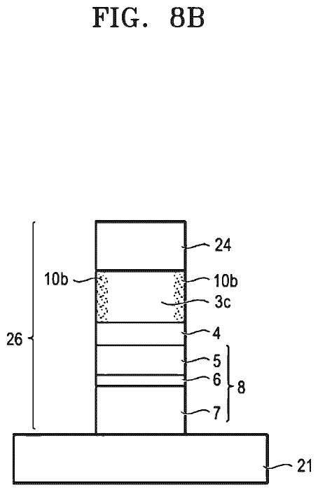

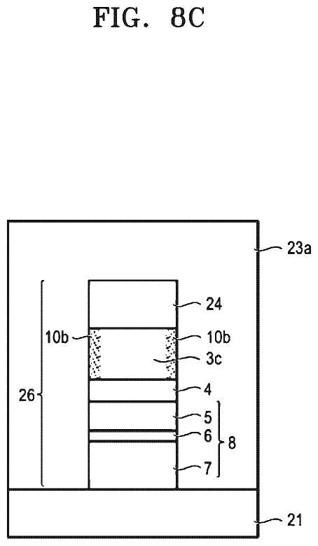

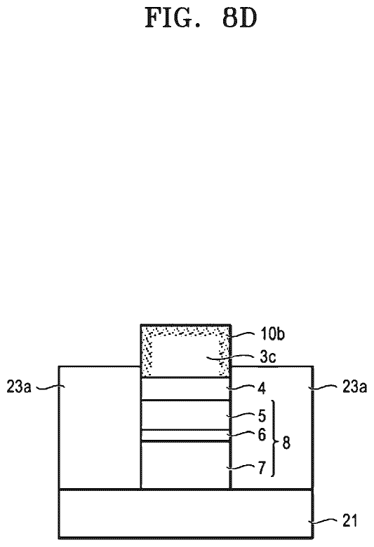

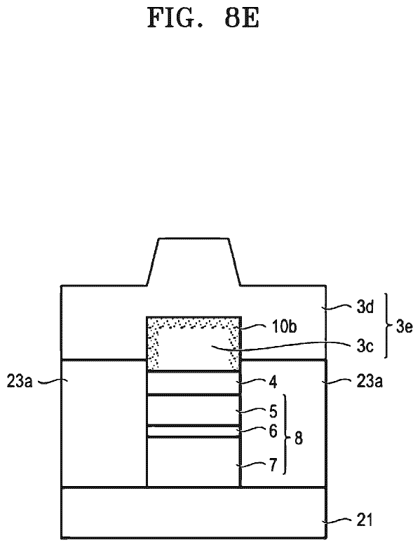

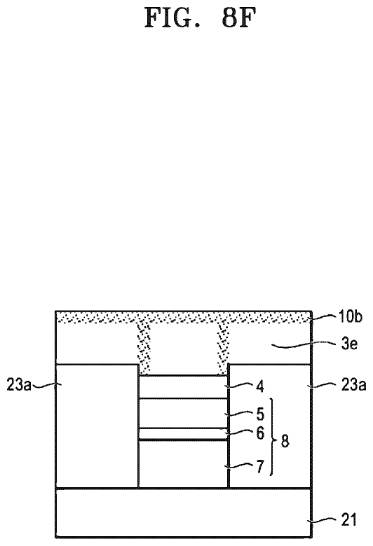

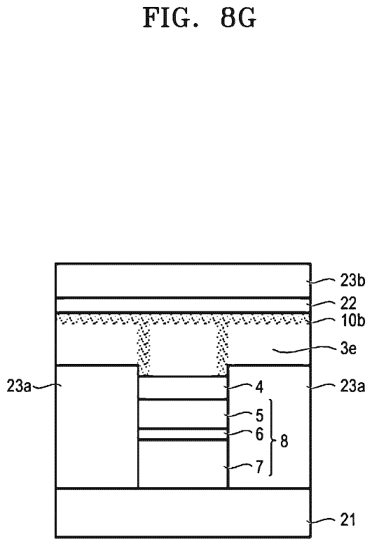

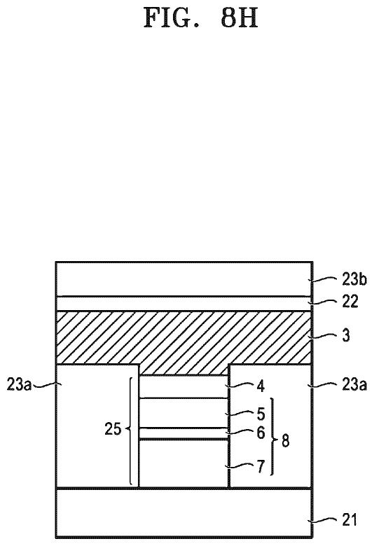

In the magnetoresistive devices illustrated in FIGS. 6 and 7, the first portion α of the BiSb film (e.g., the SOT electrode layer 3), which is arranged on the intermediate layer 4 in the pillar structure 25, and the second portion β of the BiSb film (e.g., the SOT electrode layer 3), which is arranged on the member that does not constitute the pillar structure 25, may exist continuously in terms of crystallography. That is, the first portion α of the BiSb film (e.g., the SOT electrode layer 3), which is arranged on the intermediate layer 4 in the pillar structure 25, and the second portion β of the BiSb film (e.g., the SOT electrode layer 3), which is arranged on the member that does not constitute the pillar structure 25, may have a continuous crystal structure. The fact that the first portion α of the BiSb film (e.g., the SOT electrode layer 3), which is arranged on the intermediate layer 4 in the pillar structure 25, and the second portion β of the BiSb film (e.g., the SOT electrode layer 3), which is arranged on the member that does not constitute the pillar structure 25, may exist continuously in terms of crystallography, may be confirmed, for example, by cross-sectional TEM analysis and/or cross-sectional STEM analysis as a disassembly investigation. The first portion α may be a portion derived from a first preliminary SOT electrode layer 3c as described later with respect to FIG. 8E, and the second portion β may be a portion derived from a second preliminary SOT electrode layer 3d.

Even if a plurality of regions including a first region and a second region exist integrally, when types of crystals, degrees of crystallization, and/or orientations of crystals in the first region and the second region are clearly different, it cannot be said that the first region and the second region exist continuously in terms of crystallography. In cross-sectional TEM analysis and/or cross-sectional STEM analysis, when types of crystals, degrees of crystallization, and/or orientations of crystals in the first region and the second region are clearly different, these differences may be confirmed as differences in color concentration and/or cross-sectional state in images obtained. Therefore, when no clear difference in color concentration and/or clear difference in cross-sectional state is confirmed in the images obtained from cross-sectional TEM analysis and/or cross-sectional STEM analysis, it may be determined that the first region and the second region exist continuously in terms of crystallography. In addition, when a third or more region exists, whether or not two adjacent regions exist continuously in terms of crystallography may be determined in a similar manner.

In addition, when etching damage occurs, the crystallinity deteriorates due to the etching damage, so one region that is greatly affected by the etching damage and the other region that is little or not affected by the etching damage, which are adjacent to each other, may be discontinuous in terms of crystallography. However, by undergoing the melting and crystallization process through the annealing treatment and cooling, the crystallinity in the SOT electrode layer may be improved, and these regions may exist continuously in terms of crystallography.

Hereinafter, a method of manufacturing the magnetoresistive device of Specific Example 3 will be described with reference to FIGS. 8A to 8H.

First, a base electrode 21/a ferromagnetic reference layer (e.g., a second magnetic layer 7)/a tunnel barrier layer (e.g., a non-magnetic layer 6)/a ferromagnetic recording layer (e.g., a first magnetic layer 5)/an intermediate layer 4/a BiSb film (e.g., a first preliminary SOT electrode layer 3c) may be formed on an interlayer insulating film (not shown) by sputtering, and then a hard mask layer 24 may be formed thereon (FIG. 8A).

Next, the hard mask layer 24 may be dry etched to fit a processing shape (e.g., a shape of the target pillar structure) (not shown).

Then, by using the hard mask layer 24 processed, the ferromagnetic reference layer (e.g., the second magnetic layer 7)/the tunnel barrier layer (e.g., the non-magnetic layer 6)/the ferromagnetic recording layer (e.g., the first magnetic layer 5)/the intermediate layer 4/the BiSb film (e.g., the first preliminary SOT electrode layer 3c) may be processed into a pillar shape by dry etching process to form a preliminary pillar structure 26. Due to this dry etching process, etching damage may occur on a side surface of the BiSb film (e.g., the first preliminary SOT electrode layer 3c), resulting in deterioration of crystallinity. A portion of the first preliminary SOT electrode layer 3c where etching damage exists is depicted as an etching damaged portion 10b. At this time, etching damage may also occur on side surfaces of other parts of the preliminary pillar structure 26, but since the BiSb film (e.g., the first preliminary SOT electrode layer 3c) may be particularly vulnerable to etching damage, etching damage to other parts of the pillar structure is not shown (FIG. 8B).

Then, a protective film (not shown) such as SiNx may be deposited to cover side and top surfaces of a processed pillar-shaped stack structure (e.g., the preliminary pillar structure 26), and an interlayer insulating film 23a such as SiO₂ may be deposited to cover the side and top surfaces of the pillar-shaped stack structure (e.g., the preliminary pillar structure 26) covered with the protective film. At this time, the total film thickness of the protective film and the interlayer insulating film 23a may be greater than the total film thickness from the first ferromagnetic reference layer (e.g., the second magnetic layer 7) to the hard mask layer 24, so the preliminary pillar structure 26 may be embedded in the protective film and the interlayer insulating film 23a (FIG. 8C).

Then, the interlayer insulating film 23a may be planarized and thinned by a CMP process. In addition, an etch-back process for selective etching that leaves the BiSb film (e.g., the first preliminary SOT electrode layer 3c) may be performed to thin the protective film and interlayer insulating film 23a to a height that is lower than an upper surface of the BiSb film (e.g., the first preliminary SOT electrode layer 3c) and higher than a lower surface of the BiSb film (e.g., the first preliminary SOT electrode layer 3c). At this time, the hard mask layer 24 may be etched away by appropriately selecting a dry etching gas. Due to this dry etching process, etching damage may occur on the side surface of the BiSb film (e.g., the first preliminary SOT electrode layer 3c), resulting in deterioration of crystallinity. A portion of the first preliminary SOT electrode layer 3c where etching damage exists may be depicted as an etching damaged portion 10b (FIG. 8D).

Then, a BiSb film (e.g., the second preliminary SOT electrode layer 3d) may be formed on the BiSb film (e.g., the first preliminary SOT electrode layer 3c) and the interlayer insulating film 23a by sputtering film formation. At this time, the first preliminary SOT electrode layer 3c and the second preliminary SOT electrode layer 3d may be connected to each other, and thus, may constitute a third preliminary SOT electrode layer 3e. At this time, by sputtering film formation of the second preliminary SOT electrode layer 3d (e.g., the BiSb film), a portion of the third preliminary SOT electrode layer 3e (e.g., the BiSb film) may be raised above the pillar structure, to be a raised structure (FIG. 8E).

Next, after sputtering film formation of the second preliminary SOT electrode layer 3d (e.g., the BiSb film), a planarization process (e.g., a treatment by ion milling, etc.) on the third preliminary SOT electrode layer 3e (e.g., the BiSb film) may be performed. During this planarization process, etching damage may occur on an upper surface of the third preliminary SOT electrode layer 3e (e.g., the BiSb film), resulting in deterioration of crystallinity thereof. A portion of the third preliminary SOT electrode layer 3e where etching damage exists may be depicted as an etching damaged portion 10b (FIG. 8F).

Then, an oxide cap layer (e.g., the cap layer 22) may be deposited on the third preliminary SOT electrode layer 3e (e.g., the BiSb film), and dry etching processing on the third preliminary SOT electrode layer 3e (e.g., the BiSb film) may be performed in an SOT wiring shape using a resist mask or the like. During this dry etching processing, etching damage may occur on a side surface of the third preliminary SOT electrode layer 3e (e.g., the BiSb film), resulting in deterioration of crystallinity thereof (not shown).

Then, a protective film (not shown) and an interlayer insulating film 23b may be formed on the third preliminary SOT electrode layer 3e processed in the SOT wiring shape to form a main portion of the SOT-MRAM device (FIG. 8G).

The reason why the high spin Hall angle may be obtained by using the BiSb film, which is a topological insulator, as the SOT electrode layer may be considered to be due to the surface current specific to topological insulators, which is caused by the crystal structure and electronic structure of the BiSb film. When deterioration of crystallinity occurs on the surface, side surface, and/or interior of the SOT electrode layer, the spin Hall angle and ultimately the SOT characteristics may be significantly impaired. In addition, the spin Hall conductivity, which is an indicator of SOT switching efficiency, is the product of the spin Hall angle and the electrical conductivity. Accordingly, the deterioration of the crystallinity may also lower the electrical conductivity, so the spin Hall conductivity may also deteriorate significantly due to the deterioration of the crystallinity.

Therefore, after a main portion of a device in which the third preliminary SOT electrode layer 3e (e.g., the BiSb film) is placed on top of the MTJ device 8, is completed, annealing treatment may be performed at a temperature greater than the melting point of BiSb. By this annealing treatment, the BiSb film may be first melted and then crystallized by cooling. By this melting and crystallization process, any remaining machining damage on the surface, side, and/or interior of the third preliminary SOT electrode layer 3e (e.g., the BiSb film) may be repaired, thereby forming a good crystal structure. Through this annealing treatment and subsequent cooling (e.g., the melting and crystallization process), the SOT electrode layer 3 may be formed to complete the main portion of the SOT-MRAM device. Additionally, the main portion of the SOT-MRAM device may include a pillar structure 25 (FIG. 8H).

The crystal structure of the crystallized BiSb film may depend on the type and crystal structure of the oxide cap layer (e.g., the cap layer 22) and the type and crystal structure of the intermediate layer 4. For example, for the same reason as the description of Specific Example 1, when a stack structure of “TaOₓ/TiOₓ” from the bottom is adopted as the cap layer 22, and a Ti film is adopted as the intermediate layer 4, the SOT electrode layer 3 formed from the third preliminary SOT electrode layer 3e through the melting and crystallization process may have a good crystal orientation of BiSb (012), so that the SOT-MRAM device having a larger spin Hall angle and higher electrical conductivity may be obtained.

### <Semiconductor Device and Method of Manufacturing the Same>

Another aspect of the inventive concepts relates to a semiconductor device including the magnetoresistive device according to the first or fourth embodiment. Another aspect of the inventive concepts relates to a method of manufacturing a semiconductor device, which includes manufacturing the magnetoresistive device according to the second, third or fifth embodiment, and incorporating the manufactured magnetoresistive device into the semiconductor device.

While embodiments of the inventive concepts have been described in detail, it is to be understood that the embodiments are illustrative and example, not limiting, and that the scope of the inventive concepts should be interpreted by the appended claims.

The inventive concepts may include, but is not limited to, the following forms:

A method of manufacturing a magnetoresistive device, wherein the magnetoresistive device may include: a buffer layer including at least one compound of oxide, nitride, and oxynitride; an SOT electrode layer provided on the buffer layer and configured to apply SOT to a first magnetic layer of an MTJ device by flowing current therethrough; an intermediate layer provided on the SOT electrode layer; and the MTJ device provided on the intermediate layer, wherein the MTJ device may include a first magnetic layer, a non-magnetic layer provided on the first magnetic layer, and a second magnetic layer provided on the non-magnetic layer, the method may include forming the SOT electrode layer by a method including the following (1), the following (2), the following (3), and the following (4):
(1) forming a sputtered film by sputtering a material including BiSb on the buffer layer;
(2) planarizing the sputtered film using a surface planarization process, and obtaining a planarized sputtered film;
(3) forming the intermediate layer on the planarized sputtered film; and
(4) promoting crystallization of BiSb by annealing the planarized sputtered film to a temperature of at least the melting point of BiSb after forming the intermediate layer, followed by cooling the planarized sputtered film.

[2]A method of manufacturing a magnetoresistive device, wherein the magnetoresistive device may include: a buffer layer including at least one compound of oxide, nitride, and oxynitride; an SOT electrode layer provided on the buffer layer and applying SOT to a first magnetic layer of an MTJ device by flowing current therethrough; an intermediate layer provided on the SOT electrode layer; and the MTJ device provided on the intermediate layer, wherein the MTJ device may include a first magnetic layer, a non-magnetic layer provided on the first magnetic layer, and a second magnetic layer provided on the non-magnetic layer, the method may include forming the SOT electrode layer by a method including the following (A), the following (B), and the following (C):
(A) forming an amorphous sputtered film by sputtering a material including BiSb on the buffer layer;
(B) forming the intermediate layer on the amorphous sputtered film; and
(C) promoting crystallization of BiSb by annealing the amorphous sputtered film at a temperature equal to or higher than a melting point of BiSb after forming the intermediate layer, followed by cooling the sputtered film.

[3] The method of manufacturing the magnetoresistive device as described in [1] or [2], wherein sputtering film formation of a material including the BiSb may be performed at a temperature of less than 10° C.

[4] The method of manufacturing the magnetoresistive device as described in any one of [1] to [3], wherein the planarized sputtered film or the amorphous sputtered film may have a surface roughness of about 0.5 nm or less as an arithmetic average roughness Ra, which is measured by micro-area analysis.

[5]A method of manufacturing a magnetoresistive device, the magnetoresistive device may include: a magnetic tunnel junction (MTJ) device; an intermediate layer provided on a first magnetic layer of the MTJ device; a SOT electrode layer that may apply spin-orbit torque (SOT) to the first magnetic layer by flowing a current therethrough; and a cap layer including at least one compound of oxide, nitride and oxynitride that are provided on the SOT electrode layer; wherein the MTJ device includes a second magnetic layer, a non-magnetic layer provided on the second magnetic layer, and the first magnetic layer provided on the non-magnetic layer, the magnetoresistive device may include a pillar structure including the MTJ device and the intermediate layer, the SOT electrode layer includes a first portion α disposed on the intermediate layer in the pillar structure, and a second portion β disposed on a member that does not constitute the pillar structure, the first portion α and the second portion β exist integrally, and the SOT electrode includes BiSb, and the method of manufacturing the magnetoresistive device may include forming the SOT electrode according to a method including the following (i), the following (ii), the following (iii), the following (iv), the following (v), the following (vi), and the following (vii).
(i) forming the MTJ device, the intermediate layer, and a first preliminary SOT electrode layer including BiSb in this order;
(ii) etching a stack structure portion including the MTJ device, the intermediate layer, and the first preliminary SOT electrode layer into a pillar shape to form a preliminary pillar structure including the MTJ device, the intermediate layer, and the first preliminary SOT electrode layer;
(iii) forming at least one film of a protective film and an interlayer insulating film around side and upper surfaces of the preliminary pillar structure;
(iv) exposing a portion of the first preliminary SOT electrode layer by performing at least one treatment of planarizing and thinning the at least one film of the protective film and the interlayer insulating film;
(v) forming a second preliminary SOT electrode layer including BiSb, on a surface of the first preliminary SOT electrode layer and on the at least one film of the protective film and the interlayer insulating film, in which the first preliminary SOT electrode layer and the second preliminary SOT electrode layer are connected to form a third preliminary SOT electrode layer;
(vi) forming the cap layer on the third preliminary SOT electrode layer; and
(vii) after forming the cap layer, performing crystallization of BiSb by annealing the third preliminary SOT electrode layer at a temperature of at least a melting point of BiSb and then cooling.

[6] The method of manufacturing the magnetoresistive device as described in [5], wherein the magnetoresistive device satisfies at least one of the following (I) and the following (II):
(I) The first portion α has a film thickness greater than that of the second portion β;
(II) The first portion α and the second portion β exist continuously in terms of crystallography.

[7] The method of manufacturing the magnetoresistive device as described in [5] or [6], wherein the magnetoresistive device further comprises an underlayer, and the MTJ device is provided on the underlayer, and
the SOT electrode layer has a shape having a convex portion facing the underlayer, and an underlayer-side surface of the SOT electrode layer in the first portion α is positioned closer to the underlayer than an underlayer-side surface of the SOT electrode layer in the second portion β.

[8] The method of manufacturing the magnetoresistive device as described in any one of [1] to [7], wherein a crystal structure of the SOT electrode layer has a plane orientation of a crystal plane in a plane parallel to the first magnetic layer preferentially oriented to BiSb(012) (e.g., a majority and/or plurality of the crystal grain structure is oriented to BiSb(012)), the electric conductivity of the SOT electrode layer is at least about 0.8×10⁵ Ω⁻¹ m⁻¹, and the value of the spin Hall angle, which is a conversion efficiency from electric current to spin current, is at least about 5.

[9] The method of manufacturing the magnetoresistive device as described in any one of [1] to [8], wherein at least one layer of the buffer layer and the intermediate layer, or at least one layer of the cap layer and the intermediate layer may have a crystal structure that may control the crystal orientation of the SOT electrode layer formed by melting of BiSb and subsequent crystallization thereof, and the intermediate layer includes a material whose spin diffusion length is longer than a film thickness of the intermediate layer.

[10] The method of manufacturing the magnetoresistive device as described in any one of [1] to [9], wherein the buffer layer or the cap layer may have a stack structure including two or more layers with different compositions.

[11] The method of manufacturing the magnetoresistive device as described in any one of [1] to [10], wherein the buffer layer or the cap layer may include an oxide of at least one metal of Ta, Ti, Mg, Al, Mn and/or Fe.

[12] The method of manufacturing the magnetoresistive device as described in any one of [1] to [11], wherein the intermediate layer may have a stack structure including layers with different compositions.

[13] The method of manufacturing the magnetoresistive device as described in any one of [1] to [12], wherein the intermediate layer may include at least one material of an elemental metal, an alloy of metals, a compound of a metal and a metalloid, a metal nitride, a metal oxide, a metal oxynitride, and a B—C—N based material.

[14]A method of manufacturing a semiconductor device, wherein the method may include manufacturing a magnetoresistive device according to the method described in any one of [1] to [13], and incorporating the magnetoresistive device manufactured into the semiconductor device.

[15]A magnetoresistive device, including: a buffer layer including at least one compound of oxide, nitride, and oxynitride; an SOT electrode layer provided on the buffer layer and applying SOT to a first magnetic layer of an MTJ device by flowing current therethrough; an intermediate layer provided on the SOT electrode layer; and the MTJ device provided on the intermediate layer, wherein the MTJ device may include a first magnetic layer, a non-magnetic layer provided on the first magnetic layer, and a second magnetic layer provided on the non-magnetic layer, the SOT electrode layer may include BiSb, a crystal structure of the SOT electrode layer may be such that a plane orientation of a crystal plane in a plane parallel to the first magnetic layer is preferentially oriented to BiSb(012), and a surface roughness of the SOT electrode layer measured by micro-area analysis is about 0.5 nm or less as an arithmetic average roughness Ra, an electrical conductivity of the SOT electrode layer is about 0.8×10⁵ Ω⁻¹ m⁻¹ or more, and the value of the spin Hall angle, which is the conversion efficiency from electric current to spin current, is about 5 or more.

[16]A magnetoresistive device, including: a magnetic tunnel junction (MTJ) device; an intermediate layer provided on a first magnetic layer of the MTJ device; a SOT electrode layer that may apply spin-orbit torque (SOT) to the first magnetic layer by flowing a current therethrough; and a cap layer including at least one compound of oxide, nitride and oxynitride that are provided on the SOT electrode layer; wherein the MTJ device includes a second magnetic layer, a non-magnetic layer provided on the second magnetic layer, and the first magnetic layer provided on the non-magnetic layer, the SOT electrode layer includes BiSb, and a crystal structure of the SOT electrode layer is such that the plane orientation of a crystal plane in a plane parallel to the first magnetic layer is preferentially oriented to BiSb(012), the magnetoresistive device includes a pillar structure including the MTJ device and the intermediate layer, the SOT electrode layer includes a first portion α disposed on the intermediate layer in the pillar structure, and a second portion β disposed on a member that does not constitute the pillar structure, the first portion α and the second portion β exist integrally, and the magnetoresistive device satisfies at least one of the following (1) and the following (11).
(I) The first portion α has a film thickness greater than that of the second portion β;
(II) The first portion α and the second portion β exist continuously in terms of crystallography.

[17] The magnetoresistive device as described in [16], wherein the electrical conductivity of the SOT electrode layer may be at least about 0.8×10⁵ Ω⁻¹m⁻¹, and the value of the spin Hall angle, which is the conversion efficiency from current to spin current, may be at least about 5.

[18]A magnetoresistive device as described in [16] or [17], wherein the device may further include an underlayer, the MTJ device may be provided on the underlayer, the SOT electrode layer may have a shape having a convex portion facing the underlayer, and the underlayer-side surface of the SOT electrode layer in the first portion α may be positioned closer to the underlayer than the underlayer-side surface of the SOT electrode layer in the second portion β.

[19] The magnetoresistive device as described in any one of [15] to [18], wherein at least one layer of the buffer layer and the intermediate layer, or at least one layer of the cap layer and the intermediate layer may have a crystal structure that may control the crystal orientation of the SOT electrode layer formed by melting of BiSb and subsequent crystallization thereof, and the intermediate layer includes a material whose spin diffusion length is longer than a film thickness of the intermediate layer.

[20] The magnetoresistive device as described in any one of [15] to [19], wherein the buffer layer or the cap layer may have a stack structure including two or more layers with different compositions.

[21] The magnetoresistive device as described in any one of [15] to [20], wherein the buffer layer or the cap layer may include an oxide of at least one metal of Ta, Ti, Mg, Al, Mn and Fe.

[22] The magnetoresistive device as described in any one of [15] to [21], wherein the intermediate layer may have a stack structure including layers with different compositions.

[23] The magnetoresistive device as described in any one of [15] to [22], wherein the intermediate layer may include at least one material of an elemental metal, an alloy of metals, a compound of a metal and a metalloid, a metal nitride, a metal oxide, a metal oxynitride, and a B—C—N based material.

[24]A semiconductor device including the magnetoresistive device as described in any one of [15]-[23].

While the inventive concepts have been particularly shown and described with reference to embodiments thereof, it will be understood that various changes in form and details may be made therein without departing from the spirit and scope of the following claims.

What is claimed is:

1. A method of manufacturing a magnetoresistive device, the method comprising:
forming a buffer layer on an underlayer;
forming a spin-orbit torque (SOT) electrode layer configured to apply SOT to a first magnetic layer of a magnetic tunnel junction device by flowing current on the buffer layer, the forming of the SOT electrode layer comprising
forming a sputtered film by sputtering a material containing BiSb on the buffer layer, and
forming a planarized sputtered film after planarizing the sputtered film by a surface planarization process;
forming an intermediate layer on the SOT electrode layer;
promoting crystallization of the SOT electrode layer by annealing the SOT electrode layer at a temperature greater than a melting point of BiSb and then cooling the SOT electrode layer; and
forming the magnetic tunnel junction device on the intermediate layer, the magnetic tunnel junction device comprising the first magnetic layer, a non-magnetic layer formed on the first magnetic layer, and a second magnetic layer formed on the non-magnetic layer.

2. The method of claim 1, wherein the forming of the sputtered film of the material containing BiSb is performed at 10° C. or less.

3. The method of claim 1, wherein the planarized sputtered film has a surface roughness of 0.5 nm or less as an arithmetic average roughness.

4. The method of claim 1, wherein the promoting the crystallization of the SOT electrode layer includes forming a crystal structure of the SOT electrode layer such that
a plane orientation of a crystal plane in a plane parallel to the first magnetic layer is preferentially oriented to BiSb(012),
an electrical conductivity of the SOT electrode layer is about 0.8×10⁵ Ω⁻¹m⁻¹ or more, and
a value of a spin Hall angle is about 5 or more.

5. The method of claim 1, wherein at least one of the buffer layer and the intermediate layer has a crystal structure that promotes a crystal orientation of the SOT electrode layer during the promoting the crystallization of the SOT electrode layer, and
the intermediate layer comprises a material having a spin diffusion length greater than a film thickness of the intermediate layer.

6. The method of claim 1, wherein the forming the buffer layer includes forming the buffer layer such that the buffer layer has a stack structure comprising two or more layers with different compositions, and such that the buffer layer comprises an oxide of at least one metal of Ta, Ti, Mg, Al, Mn, or Fe.

7. The method of claim 1, wherein the forming the intermediate layer includes forming the intermediate layer such that the intermediate layer has a stack structure comprising layers with different compositions, and such that the intermediate layer comprises at least one material of an elemental metal, an alloy of metals, a compound of a metal and a metalloid, a metal nitride, a metal oxide, a metal oxynitride, or a B—C—N based material.

8. A method of manufacturing a magnetoresistive device, the method comprising:
forming a buffer layer on an underlayer;
forming a spin-orbit torque (SOT) electrode layer such that the SOT electrode layer is configured to apply SOT to a first magnetic layer of a magnetic tunnel junction device by flowing current on the buffer layer, the forming of the SOT electrode layer including forming an amorphous sputtered film by sputtering a material containing BiSb;
forming an intermediate layer on the SOT electrode layer;
promoting crystallization of the SOT electrode layer by annealing the SOT electrode layer at a temperature greater than a melting point of BiSb and then cooling the SOT electrode layer; and
forming the magnetic tunnel junction device on the intermediate layer, the magnetic tunnel junction device comprising the first magnetic layer, a non-magnetic layer formed on the first magnetic layer, and a second magnetic layer formed on the non-magnetic layer.

9. The method of claim 8, wherein the forming of the amorphous sputtered film is performed at a temperature of less than about 10° C.

10. The method of claim 8, wherein the amorphous sputtered film has a surface roughness of about 0.5 nm or less as an arithmetic average roughness.

11. The method of claim 8, wherein a crystal structure of the SOT electrode layer is such that
a plane orientation of a crystal plane in a plane parallel to the first magnetic layer is preferentially oriented to BiSb(012),
an electrical conductivity of the SOT electrode layer is about 0.8×10⁵ Ω⁻¹m⁻¹ or more, and
a value of a spin Hall angle is about 5 or more.

12. The method of claim 8, wherein at least one of the buffer layer and the intermediate layer has a crystal structure that promotes a crystal orientation of the SOT electrode layer during the promoting the crystallization of the SOT electrode layer, and
the intermediate layer comprises a material having a spin diffusion length greater than a film thickness of the intermediate layer.

13. The method of claim 9, wherein the forming the intermediate layer includes forming the intermediate layer such that the intermediate layer has a stack structure comprising layers with different compositions, and such the intermediate layer comprises at least one material of an elemental metal, an alloy of metals, a compound of a metal and a metalloid, a metal nitride, a metal oxide, a metal oxynitride, or a B—C—N based material.

14. A method of manufacturing a magnetoresistive device, the method comprising:
sequentially forming a magnetic tunnel junction device, an intermediate layer, and a first preliminary spin-orbit torque (SOT) electrode layer containing BiSb, on a base electrode, wherein the magnetic tunnel junction device comprises a first magnetic layer, a non-magnetic layer formed on the first magnetic layer, and a second magnetic layer formed on the non-magnetic layer;
etching the magnetic tunnel junction device, the intermediate layer, and the first preliminary SOT electrode layer to form a preliminary pillar structure, the preliminary pillar structure comprising the magnetic tunnel junction device, the intermediate layer, and the first preliminary SOT electrode layer;
forming an interlayer insulating film on side and upper surfaces of the preliminary pillar structure;
removing a portion of the interlayer insulating film to expose a portion of an upper portion of the first preliminary SOT electrode layer;
forming a second preliminary SOT electrode layer containing BiSb on a surface of the exposed portion of the first preliminary SOT electrode layer and the interlayer insulating film such that a third preliminary SOT electrode layer is formed in which the first preliminary SOT electrode layer is connected to the second preliminary SOT electrode layer;
forming a cap layer on the third preliminary SOT electrode layer; and
forming a SOT electrode layer by crystallizing the third preliminary SOT electrode layer after forming the cap layer, the crystallizing the third preliminary SOT electrode layer including annealing the third preliminary SOT electrode layer at a temperature greater than a melting point of BiSb and then cooling the third preliminary SOT electrode layer.

15. The method of claim 14, further comprising:
planarizing an upper surface of the third preliminary SOT electrode layer prior to the forming of the cap layer on the third preliminary SOT electrode layer.

16. The method of claim 15, wherein the SOT electrode layer comprises a first portion derived from the first preliminary SOT electrode layer and a second portion derived from the second preliminary SOT electrode layer, and
the first portion and the second portion have continuous crystallography.

17. The method of claim 16, wherein the first portion of the SOT electrode layer has a convex shape toward the base electrode, compared to the second portion.

18. The method of claim 14, wherein, in the removing of the portion of the interlayer insulating film to expose the portion of the upper portion of the first preliminary SOT electrode layer, the portion of the interlayer insulating film is removed such that an upper surface of the interlayer insulating film is located below the upper surface of the first preliminary SOT electrode layer and above a lower surface of the first preliminary SOT electrode layer.

19. The method of claim 14, wherein the crystallization the SOT electrode layer includes forming a crystal structure of the SOT electrode layer such that
a plane orientation of a crystal plane in a plane parallel to the first magnetic layer is preferentially oriented to BiSb(012),
an electrical conductivity of the SOT electrode layer is about 0.8×10⁵ Ω⁻¹m⁻¹ or more, and
a value of a spin Hall angle, which is conversion efficiency from current to spin current, is about 5 or more.

20. The method of claim 14, wherein at least one of the intermediate layer, the cap layer, or the intermediate layer, has a crystal structure that promotes a crystal orientation of the SOT electrode layer during the crystallization of the SOT electrode layer, and
the intermediate layer comprises a material having a spin diffusion length greater than a film thickness of the intermediate layer.
